(19) United States
(12) Patent Application Publication
(10) Pub. No.: US 2011/0188288 A1
(43) Pub. Date: Aug. 4, 2011

(54) SEMICONDUCTOR MEMORY DEVICE AND DRIVING METHOD THEREFOR

(75) Inventor: Yoshihiro MINAMI, Yokosuka-Shi (JP)

(73) Assignee: KABUSHIKI KAISHA TOSHIBA, Tokyo (JP)

(21) Appl. No.: 12/822,952

(22) Filed: Jun. 24, 2010

(30) Foreign Application Priority Data
Feb. 4, 2010 (JP) 2010-23369

(51) Int. Cl. G11C 11/22; H01L 27/115

(52) U.S. Cl. 365/145; 257/295; 257/E27.104

(57) ABSTRACT

A memory includes a first conductive-type first diffusion layer on the semiconductor substrate; second conductive-type bodies on the first diffusion layer(s); first conductive-type second diffusion layers on the bodies; first gate dielectric films comprising ferroelectric films and provided on first side surfaces of the bodies; second gate dielectric films comprising ferroelectric films and provided on second side surfaces of the bodies; first gate electrodes on the first gate dielectric film; and second gate electrodes on the second gate dielectric film, wherein the first and the second diffusion layers, the body, the first and the second gate dielectric films, and the first and the second gate electrodes constitute memory cells, and each of the memory cells stores a plural pieces of logical data depending on a polarization state of the first gate dielectric film and on a polarization state of the second gate dielectric film.

### CROSS-REFERENCE TO RELATED APPLICATION

This application is based upon and claims the benefit of priority from the prior Japanese Patent Applications No. 2010-23369, filed on Feb. 4, 2010, the entire contents of which are incorporated herein by reference.

### FIELD

The embodiments of the present invention relate to a semiconductor memory device and a driving method thereof.

### BACKGROUND

In recent years, ferro-electric random access memories (FeRAMs) with a ferroelectric film have been commanding attention as one of non-volatile semiconductor memories (see IEEE ED letters, Vol. 25, No. 6, June 2004, pp. 369-371, hereinafter, “Non-Patent Document 1”). A MOS transistor described in Non-Patent Document 1 is a memory using a ferroelectric film for a gate oxide film and storing data depending on a polarization state of the ferroelectric film. Such a ferroelectric memory can store 1-bit data in one transistor and does not require any capacitors. Thus, the ferroelectric memory is excellent in its downscaling as compared to conventional DRAMs. However, to further increase the memory capacity of the ferroelectric memory, its unit cell size needs to be reduced further. In this respect, it is not easy to further reduce the cell size because of limitations in manufacturing processes.

### BRIEF DESCRIPTION OF THE DRAWINGS

FIG. 1 is a perspective view schematically showing a configuration of a double gate ferroelectric memory according to a first embodiment of the present invention;

FIG. 2 is a schematic plan view of the double gate ferroelectric memory according to the first embodiment;

FIGS. 3A and 3B are schematic cross-sectional views of the double gate ferroelectric memory according to the first embodiment;

FIGS. 4 to 21B are perspective views and cross-sectional views showing a manufacturing method of the double gate vertical ferroelectric memory according to the first embodiment;

FIGS. 22A and 22B are cross-sectional views of a double gate ferroelectric memory according to a first modification of the first embodiment;

FIG. 23 is a block diagram showing a configuration of cell array and periphery of the double gate ferroelectric memory according to the first embodiment or the first modification;

FIGS. 24 to 28 are circuit diagrams showing the driving method of a double gate ferroelectric memory according to the first embodiment;

FIGS. 29A and 29B are cross-sectional views showing a configuration of a double gate ferroelectric memory according to a second embodiment of the present invention;

FIGS. 30A to 50B are cross-sectional views showing a manufacturing method of the double gate vertical ferroelectric memory according to the second embodiment; and

FIGS. 51A and 51B are cross-sectional views of a double gate ferroelectric memory according to a first modification of the second embodiment.

### DETAILED DESCRIPTION

Embodiments of the present invention will be explained below in detail with reference to the accompanying drawings. Note that the present invention is not limited thereto.

### First Embodiment

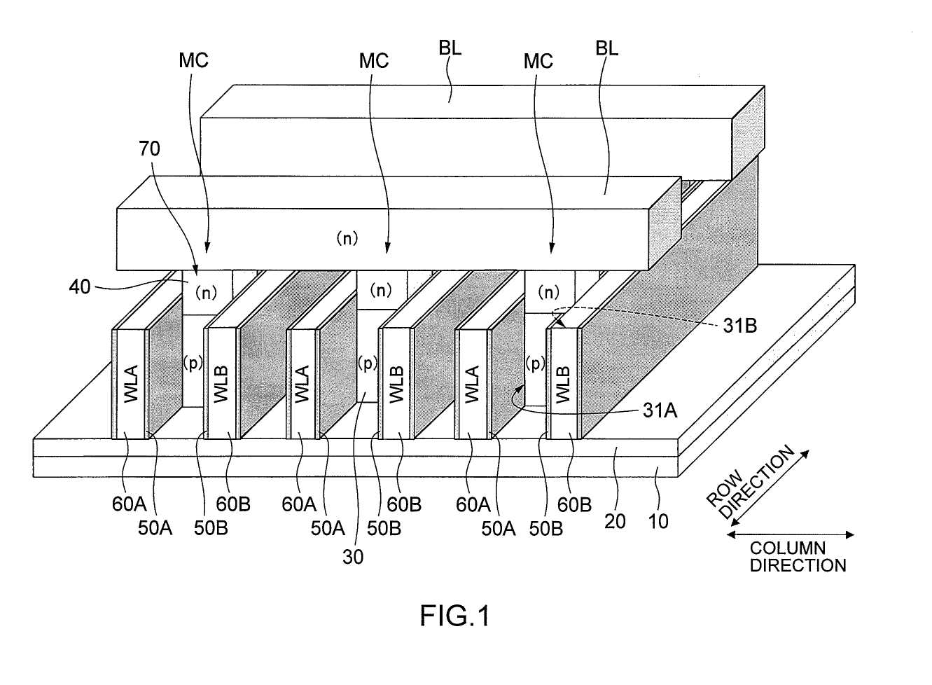

FIG. 1 is a perspective view schematically showing a configuration of a double gate ferroelectric memory according to a first embodiment of the present invention. The double gate ferroelectric memory comprises a silicon substrate 10 as a semiconductor substrate, an N-type source layer 20 as a first diffusion layer, a P-type body region 30, a drain layer 40 as a second diffusion layer, a first gate dielectric film 50A, a second gate dielectric film 50B, a first gate electrode 60A, a second gate electrode 60B, and a bit line BL.

The source layer 20 is formed on a surface of the silicon substrate 10 so as to be common to all the body regions 30. The body region 30 is provided on the source layer 20. The drain layer 40 is provided on the body region 30. The body region 30 and the drain layer 40 constitute a pillar 70 made of silicon (hereinafter, also silicon pillar 70). The silicon pillar 70 is silicon integrally formed in an elongated pillar shape. The silicon pillar 70 is provided so as to correspond to each memory cell MC.

The first gate dielectric film 50A is provided on a first side surface 31A of the body region 30 and includes a ferroelectric film. The second gate dielectric film 50B is provided on a second side surface 31B (not shown in FIG. 1) of the body region 30 which is opposite to the first side surface 31A. The first gate electrode 60A is provided on the first side surface 31A of the body region 30 with the first gate dielectric film 50A interposed therebetween. The second gate electrode 60B is provided on the second side surface 31B of the body region 30 with the second gate dielectric film 50B interposed therebetween. In this manner, the gate electrodes 60A and 60B are provided on the side surfaces of the body region 30 with the gate dielectric films 50A and 50B interposed therebetween, respectively. Accordingly, each of the memory cell MC includes a vertical double gate transistor.

The bit line BL extends in a column direction and is connected to the drain layers 40 of the silicon pillars 70 arranged in the column direction. The first and second gate electrodes 60A and 60B also function as a first word line WLA and a second word line WLB, respectively. The first word line WLA is electrically separated from the second word line WLB. The first and second word lines WLA and WLB extend in a row direction perpendicular to the column direction.

The source layer 20, the silicon pillar 70 (that is, the body region 30 and the drain layer 40), the gate dielectric film 50A (or 50B), and the gate electrode 60A (or 60B) constitute the memory cell MC. A plurality of the memory cells MC arranged in the column direction share the bit line BL and a plurality of the memory cells MC arranged in the row direction share word lines WLA and WLB.

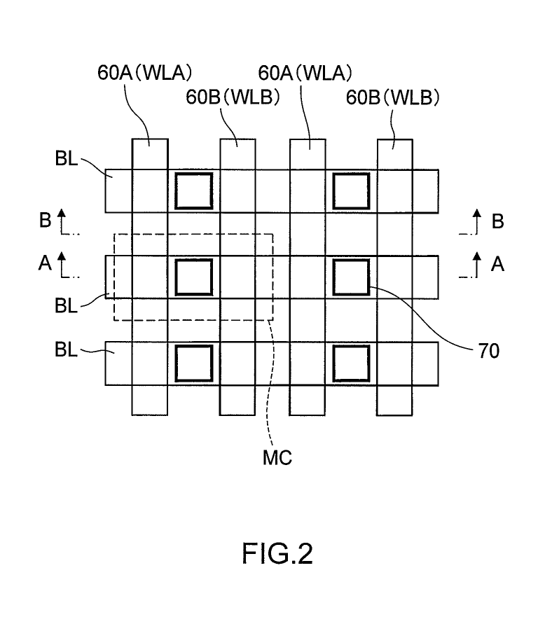

FIG. 2 is a schematic plan view of the double gate ferroelectric memory according to the first embodiment. A plurality of bit lines BL extend in the column direction so as to be formed in stripes. A plurality of the word lines WLA and WLB extend in the row direction so as to be formed in stripes.

In the plan view, the silicon pillar 70 is arranged between a word line pair (WLA and WLB) including two word lines WLA and WLB, that is, between the first word line WLA and the second word line WLB. The bit line BL is perpendicular to the word line pair (WLA and WLB) and the silicon pillar 70 is provided at an intersection of the bit line BL and the word line pair (WLA and WLB). That is, one silicon pillar 70 is provided for two intersections of the two word lines WLA and WLB and one bit line BL.

A broken line frame in FIG. 2 shows a unit of the memory cell MC. Such unit of the memory cell MC is formed repeatedly in the row direction and the column direction.

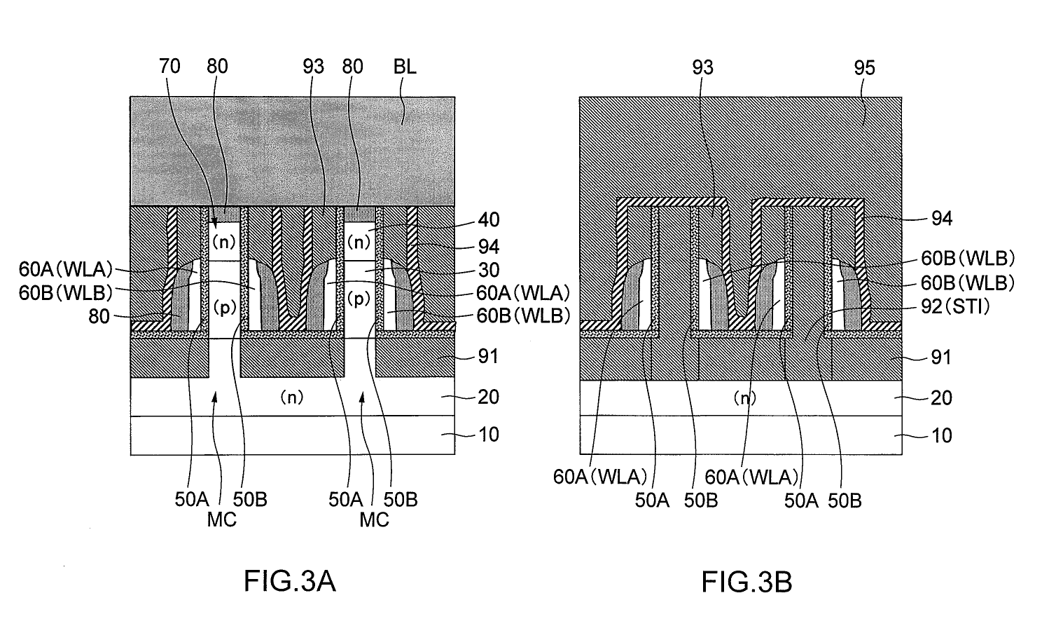

FIGS. 3A and 3B are schematic cross-sectional views of the double gate ferroelectric memory according to the first embodiment. FIGS. 3A and 3B show the double gate ferroelectric memory of the first embodiment in greater detail than the perspective view of FIG. 1. FIG. 3A is a cross-sectional view along a line A-A shown in FIG. 2. FIG. 3B is a cross-sectional view along a line B-B shown in FIG. 2.

As shown in FIG. 3A, the body region 30 contacts the common source layer 20. A silicide layer 80 is formed on the gate electrodes 60A and 60B to reduce a gate resistance. The silicide layer 80 is also provided on the drain layer 40 to reduce a contact resistance between the bit line BL and the drain layer 40. To prevent hydrogen which may deteriorate ferroelectric films from entering, a barrier metal such as Ti or TiN can be formed between the silicide layer 80 and the bit line BL.

To electrically separate the gate electrode 60A from the gate electrode 60B, insulating films 93 and 94 are formed between the gate electrode 60A and the gate electrode 60B. The insulating film 93 is, for example, a silicon oxide film and the insulating film 94 is, for example, a silicon nitride film. While the first gate dielectric film 50A and the second gate dielectric film 50B adjacent to the first gate dielectric film 50A are connected to each other under the gate electrodes 60A and 60B and the insulating film 94, problems do not occur because the first gate dielectric film 50A and the second gate dielectric film 50B are made of non-conductive ferroelectric films. An insulating film 91 is provided further under the gate electrodes 60A and 60B and the insulating film 94. The insulating film 91 makes a gap between the gate electrodes 60A and 60B and the source layer 20 longer to prevent disturbs between the memory cells MC through the common source layer 20.

As shown in FIG. 3B, an STI (Shallow Trench Isolation) 92 is formed between the gate dielectric films 50A and 50B in the cross-section along the line B-B in FIG. 2. With this arrangement, the silicon pillars 70 adjacent to each other in the row direction are electrically isolated from each other. Accordingly, one silicon pillar 70 corresponds to one memory cell MC.

The first gate dielectric film 50A and the second gate dielectric film 50B are made of ferroelectric materials with polarization characteristics, for example, SBT(SrBi₂Ta₂O₉), PZT(Pb(ZrₓTi₍₁₋ₓ₎)O₃), or BLT((Bi, La)₄Ti₃O₁₂). The first gate dielectric film 50A and the second gate dielectric film 50B can be made of the same ferroelectric material or of different ferroelectric materials from each other. To simplify a manufacturing process, the first gate dielectric film 50A and the second gate dielectric film 50B are preferably made of the same ferroelectric material. Meanwhile, to easily detect polarization states of the first gate dielectric film 50A and the second gate dielectric film 50B (that is, to read 2-bit data easily), the first gate dielectric film 50A and the second gate dielectric film 50B can be made of different ferroelectric materials from each other.

The gate electrodes 60A and 60B (the word lines WLA and WLB) are made of doped polysilicon, for example. The silicide layer 80 is made of cobalt silicide, titanium silicide, or nickel silicide, for example.

The silicon pillar 70 is formed integrally with the silicon substrate 10. The drain layer 40, the body region 30, and the source layer 20 are separated from each other by implanting impurities. The bit line BL is made of copper or tungsten, for example.

The first gate dielectric film 50A and the second gate dielectric film 50B made of ferroelectric films are provided on the side surfaces of the body region 30 of the memory cell MC according to the first embodiment. The polarization characteristic of the first gate dielectric film 50A is controlled by the voltage of the first gate electrode 60A. The polarization characteristic of the second gate dielectric film 50B is controlled by the voltage of the second gate electrode 60B. The first gate electrode 60A and the second gate electrode 60B are isolated and thus different voltages can be applied to the first gate dielectric film 50A and the second gate dielectric film 50B. That is, the polarization characteristic of the first gate dielectric film 50A can be different from that of the second gate dielectric film 50B in the same memory cell MC.

When a negative voltage is applied to the gate electrode 60A (or 60B) to polarize the gate dielectric film 50A (or 50B), the polarization characteristic of the gate dielectric film 50A (or 50B) under such a state is called negative polarization. On the other hand, when a positive voltage is applied to the gate electrode 60A (or 60B) to polarize the gate dielectric film 50A (or 50B), the polarization characteristic of the gate dielectric film 50A (or 50B) under such a state is called positive polarization.

In the memory cell MC, four states are provided. That is, the state (0, 0) that the polarization states of the gate dielectric films 50A and 50B are the negative polarization, the state (0, 1) that the polarization state of the gate dielectric film 50A is the negative polarization and the polarization state of the gate dielectric film 50B is the positive polarization, the state (1, 0) that the polarization state of the gate dielectric film 50A is the positive polarization and the polarization state of the gate dielectric film 50B is the negative polarization, and the state (1, 1) that the polarization states of the gate dielectric films 50A and 50B are the positive polarization are provided. Accordingly, one memory cell MC can store four-value data (0, 0), (0, 1), (1, 0), and (1, 1). That is, each memory cell can store 2-bit data. In this manner, because each memory cell MC can store 2-bit data in the double gate ferroelectric memory of the first embodiment, its memory capacity can be increased as compared to conventional ferroelectric memories. The double gate ferroelectric memory of the first embodiment includes a vertical transistor that the source layer 20 and the drain layer 40 are arranged in a vertical direction of the body region 30. According to the vertical transistor, the source layer, the body region, and the drain layer are formed in the vertical direction with respect to the surface of the silicon substrate 10. When data is read from the memory cell MC, a current flows in the body region 30 in a direction substantially vertical to the surface of the silicon substrate 10. As the vertical transistor (Fin-FET) is used as the memory cell MC, a unit of the memory cell MC is reduced in the double gate ferroelectric memory of the first embodiment as compared to conventional ferroelectric memories. Therefore, the memory capacity can be further increased in the first embodiment as compared to the conventional ferroelectric memories. That is, according to the double gate ferroelectric memory of the first embodiment, 2-bit data can be stored in one memory cell MC and the size of the memory cell MC can be reduced. Therefore, the memory capacity can be increased significantly in the first embodiment as compared to the conventional ferroelectric memories.

Materials and shapes of the insulating films 91 to 94 are not limited to the ones shown in FIGS. 3A and 3B.

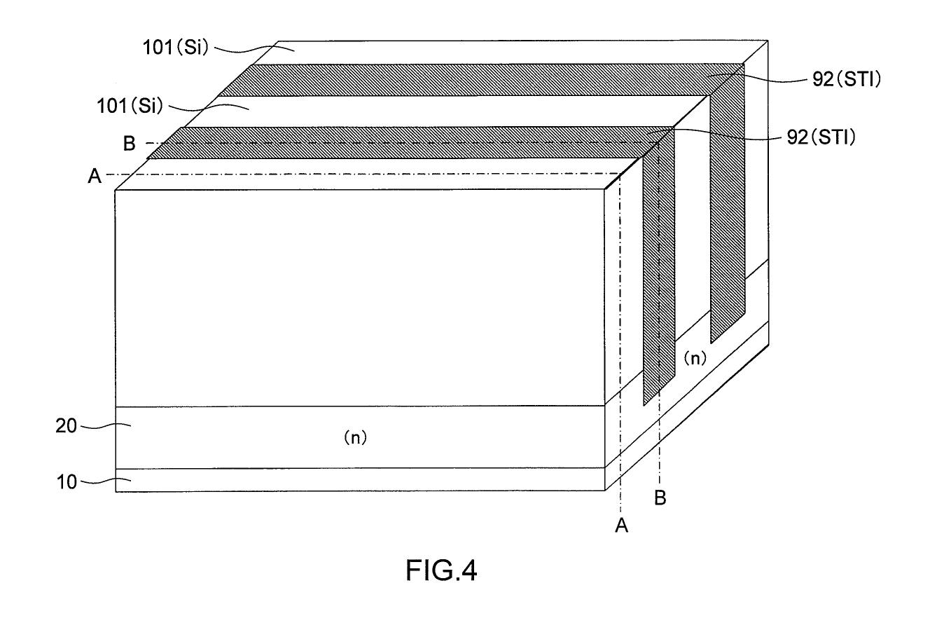

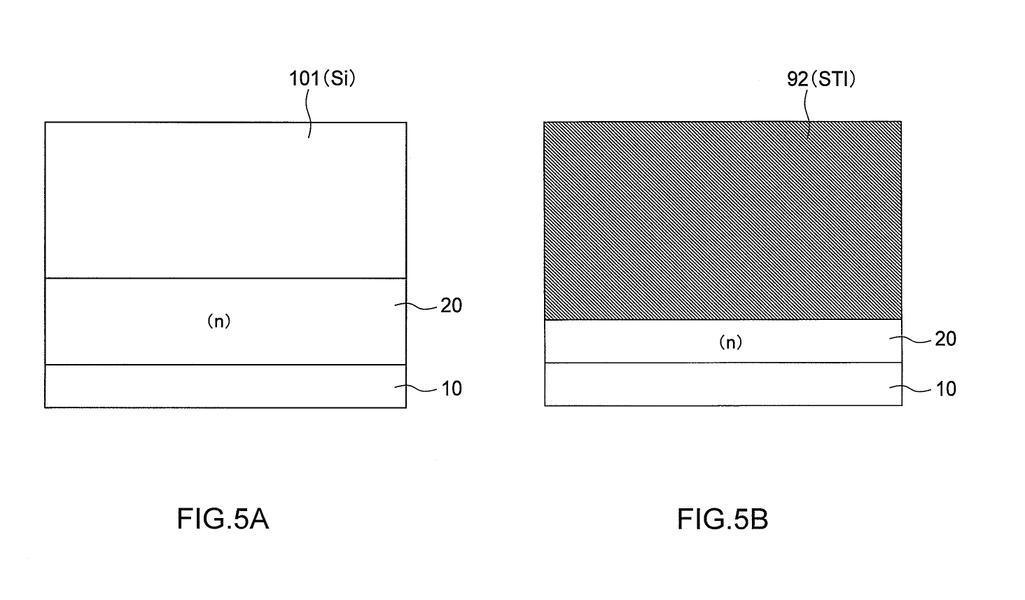

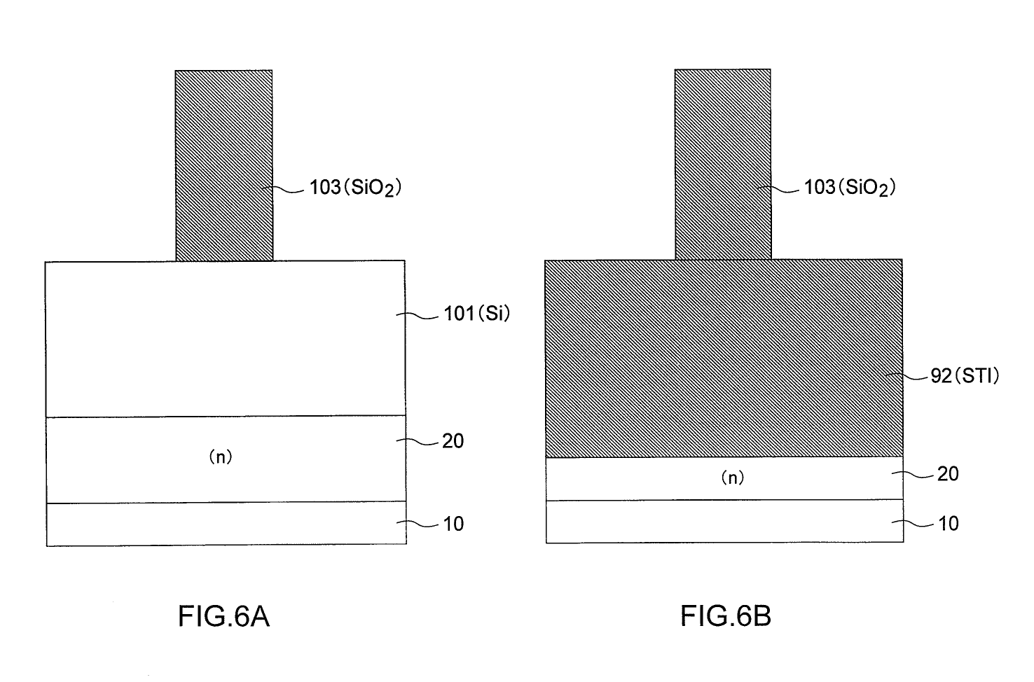

FIGS. 4 to 21B are perspective views and cross-sectional views showing a manufacturing method of the double gate vertical ferroelectric memory according to the first embodiment. First, as shown in FIG. 4, the buried N-type source layer 20 is formed in the silicon substrate 10 by highly accelerated ion implantation or the like. The STI 92 is then formed in a stripe by an STI isolation step so as to extend in the column direction. With this arrangement, a silicon layer 101 is formed between adjacent STIs 92. The silicon layer 101 is also formed in a stripe so as to extend in the column direction. The STI 92 is formed so as to reach at least the source layer 20. FIGS. 5A and 5B are cross-sectional views along lines A-A and B-B in FIG. 4, respectively. The drawings of FIGS. 6 to 21 with a letter “A” attached thereto correspond to cross-sections subsequent to the cross-section of FIG. 5A, and the drawings shown in FIGS. 6 to 21 with a letter “B” attached thereto correspond to cross-sections subsequent to the cross-section of FIG. 5B.

A silicon oxide film 103 as a mask is deposited on the silicon layer 101 and the STI 92. Next, as shown in FIGS. 6A and 6B, the silicon oxide film 103 is processed by lithography and RIE (Reactive Ion Etching). At this time, the silicon oxide film 103 is formed in a stripe so as to extend in the row direction perpendicular to a direction that the silicon layer 101 and the STI 92 extend.

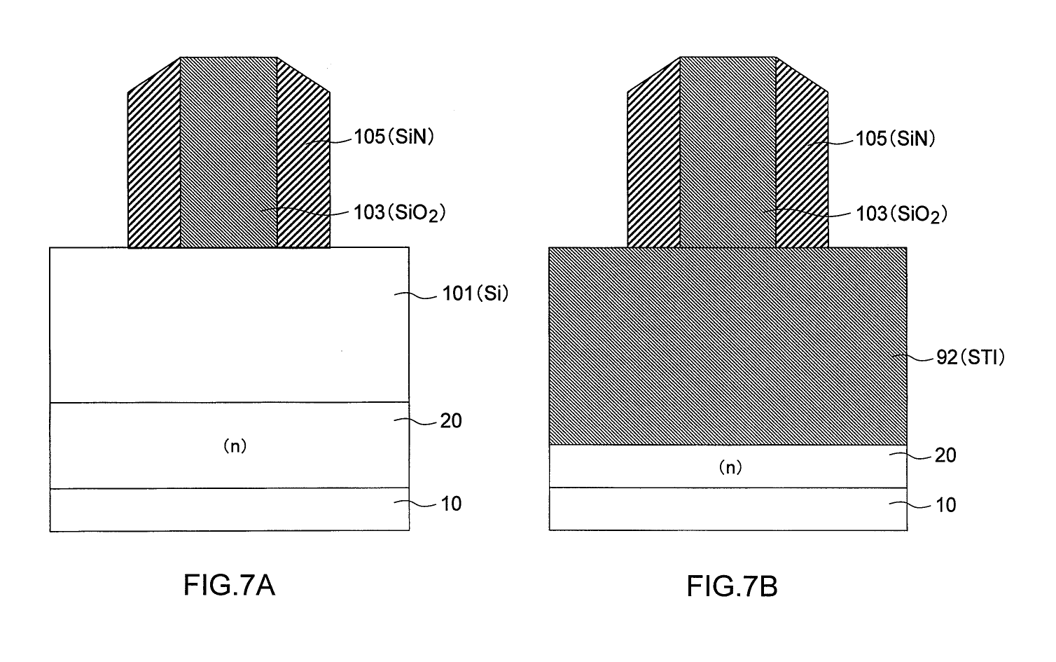

A silicon nitride film 105 is then deposited on the silicon layer 101, the STI 92, and the silicon oxide film 103 and anisotropically etched by RIE. Consequently, the silicon nitride film 105 remains as a sidewall of the silicon oxide film 103 as shown in FIGS. 7A and 7B.

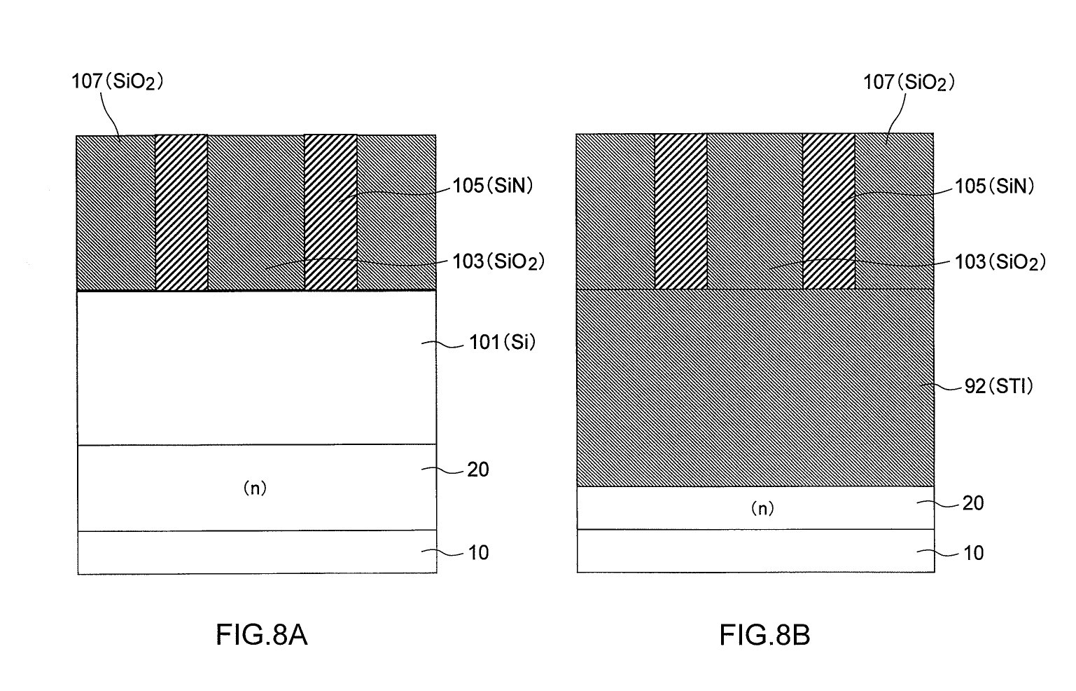

A silicon oxide film 107 is then deposited so as to be buried in a trench between adjacent silicon oxide films 103. Thereafter, the silicon oxide films 103 and 107 and the silicon nitride film 105 are ground by CMP (Chemical Mechanical Polishing) so that their surfaces are flattened. With this process, a configuration shown in FIGS. 8A and 8B is obtained.

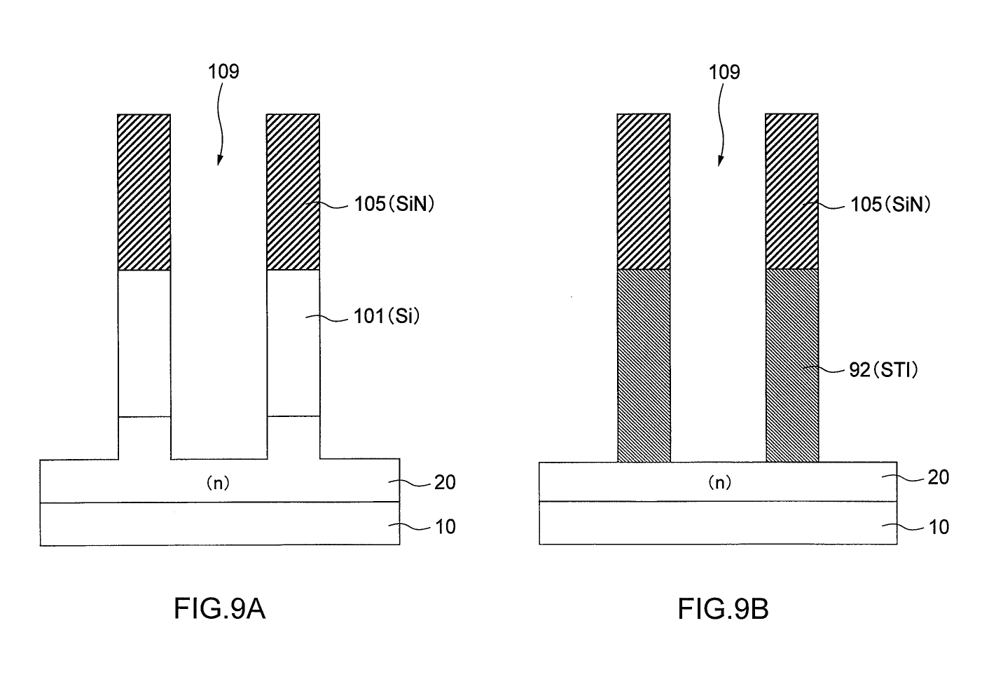

The silicon oxide films 103 and 107, the STI 92, and the silicon layer 101 are then etched by RIE using the silicon nitride film 105 as a mask. With this process, a configuration shown in FIGS. 9A and 9B is obtained. Such etching allows trenches 109 between adjacent silicon layers 10 and between adjacent STIs 92 to reach the source layer 20.

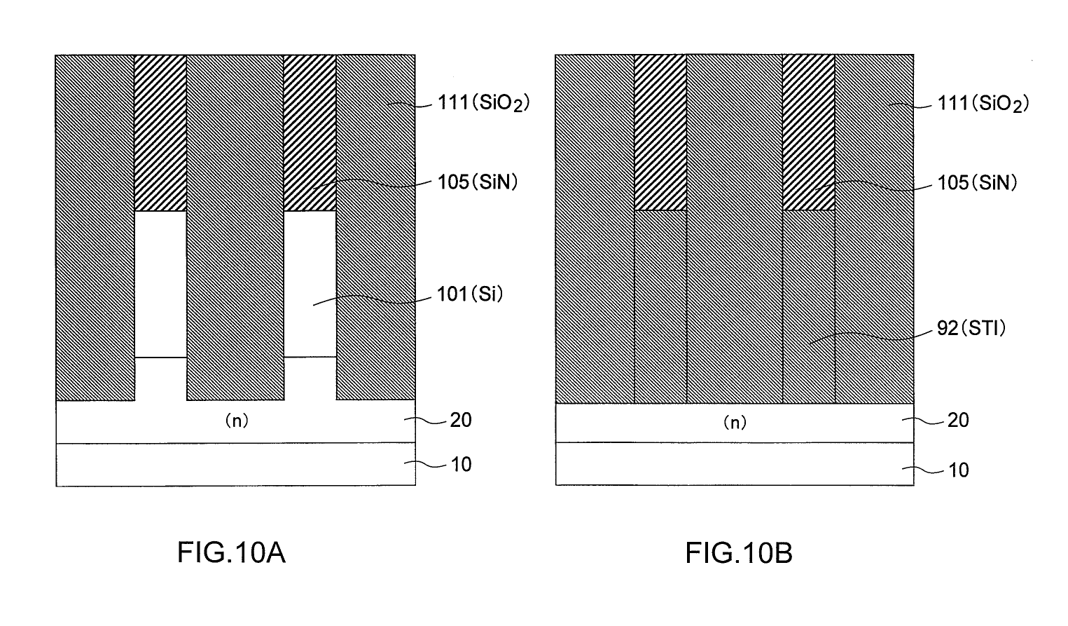

Next, as shown in FIGS. 10A and 10B, a silicon oxide film 111 is deposited in the trench 109 and its surface is flattened by CMP. The silicon oxide film 111 is thus buried in the trench 109.

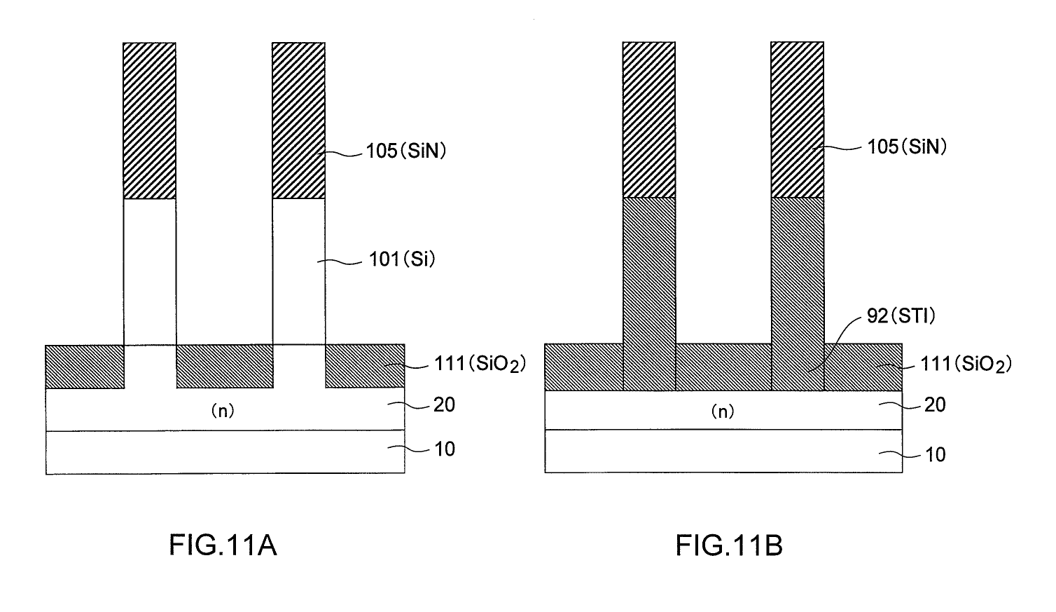

Next, as shown in FIGS. 11A and 11B, the silicon oxide film 111 is selectively etched back by RIE. The silicon oxide film 111 is etched so that its top surface is almost as high as the boundary between the source layer 20 and the silicon layer 101.

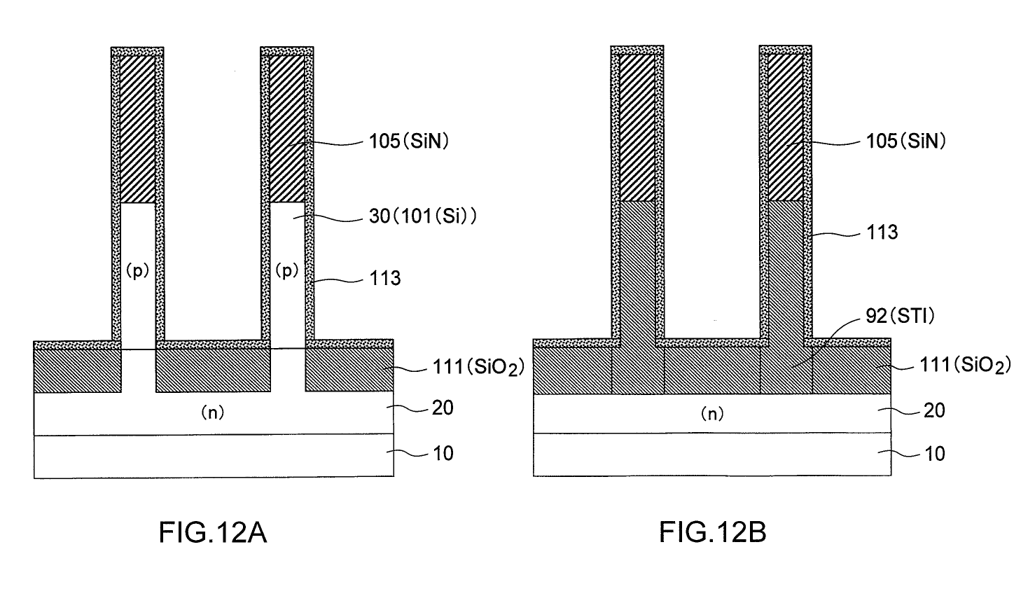

A P-type impurity (for example, boron) is then implanted in the silicon layer 101 by oblique ion implantation, so that a P-type body region 30 is formed. Thereafter, as shown in FIGS. 12A and 12B, a ferroelectric film 113 which becomes the first gate dielectric film 50A and the second gate dielectric film 50B is deposited on the side surfaces of the body region 30 and of the silicon nitride film 105 by a CVD (Chemical Vapor Deposition) process or the like. The ferroelectric films 113 as the first and second gate dielectric films 50A and 50B are formed simultaneously in a same step in the first embodiment. Therefore, the material, conductive type, thickness, and height of the first gate dielectric film 50A are substantially the same as those of the second gate dielectric film 50B. Accordingly, although flexibility of the memory configuration is limited in the first embodiment, the manufacturing process is simplified.

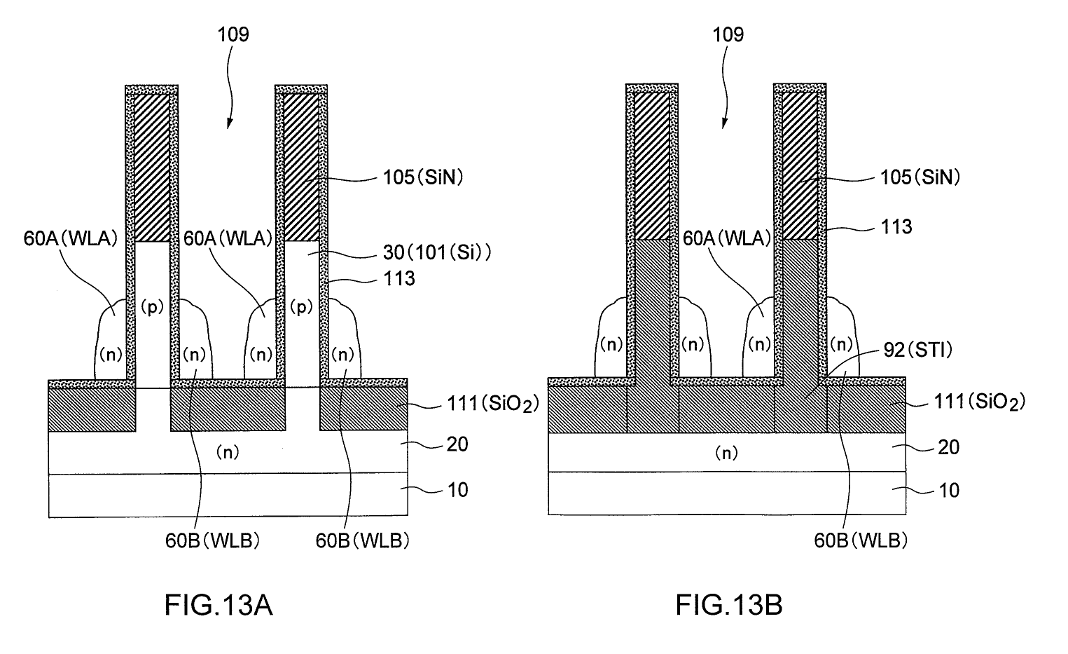

Polysilicon is then deposited while doping an N-type impurity (for example, phosphorus or arsenic). At this time, the thickness of polysilicon deposited is sufficiently smaller than ½ of width of the trench 109 (that is, a gap between adjacent body regions 30) so that the trench 109 is not filled. Thereafter, the polysilicon is anisotropically etched by RIE, so that the first gate electrode 60A and the second gate electrode 60B made of doped polysilicon remain outside the ferroelectric film 113 on the side surface of the body region 30 as shown in FIGS. 13A and 13B. That is, the first and second gate electrodes 60A and 60B are formed outside the ferroelectric film 113 as a sidewall for the side surface of the body region 30. The first and second gate electrode 60A and 60B are utilized as a mask when the boundary between the body region 30 and the drain layer 40 is determined. Accordingly, it is important to control the height of the first and second gate electrodes 60A and 60B.

According to the first embodiment, the first and second gate electrodes 60A and 60B are formed simultaneously in the same step. Thus, material, conductive type, thickness, and height of the first gate electrode 60A are substantially the same as those of the second gate electrode 60B. Accordingly, although flexibility of the memory configuration is limited in the first embodiment, the manufacturing process is simplified.

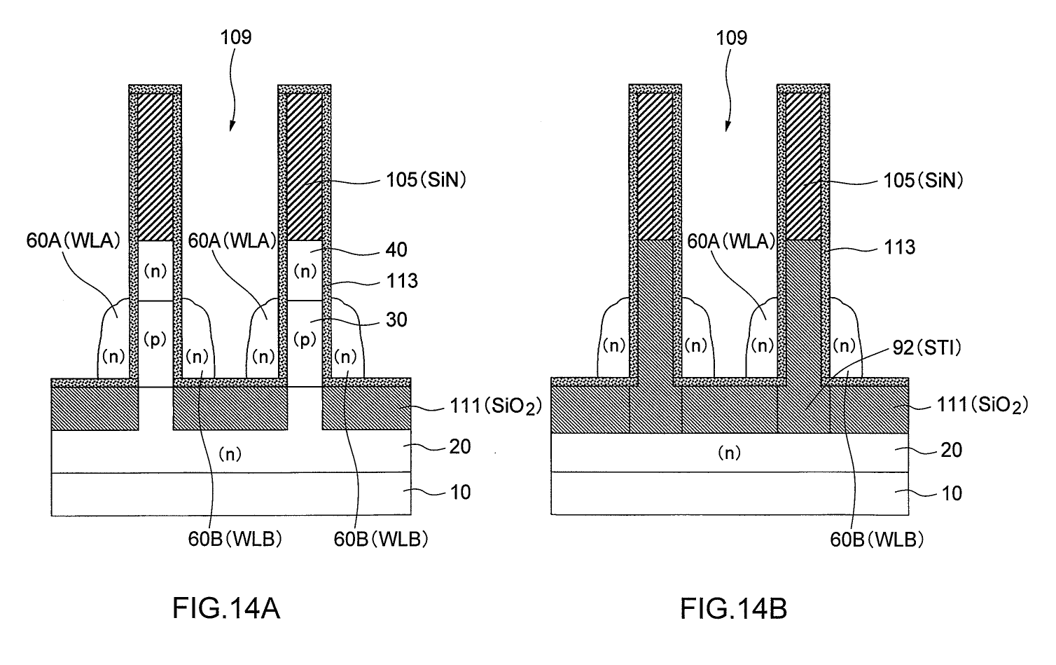

An N-type impurity (for example, phosphorus or arsenic) is then implanted in the silicon layer 101 by oblique ion implantation using the gate electrodes 60A and 60B as a mask and activated by thermal treatment. With this process, as shown in FIGS. 14A and 14B, the N-type drain layer 40 is formed. The N-type drain layer 40 is formed in a self-aligned manner by using the gate electrodes 60A and 60B as a mask. With this formation, the heights (lengths) of the drain layer 40 and the body region 30 are determined depending on the height of the gate electrodes 60A and 60B. By implanting simultaneously an impurity in the silicon oxide film 111 in the vertical direction at the time of forming the N-type drain layer 40, an N-type impurity can be also implanted in the gate electrodes 60A and 60B and the source layer 20 utilizing scattering in the silicon oxide film 111. That is, implanting an impurity in the gate electrodes 60A and 60B and forming the source layer 20 can be performed in a self-aligned manner by using the gate electrodes 60A and 60B as a mask.

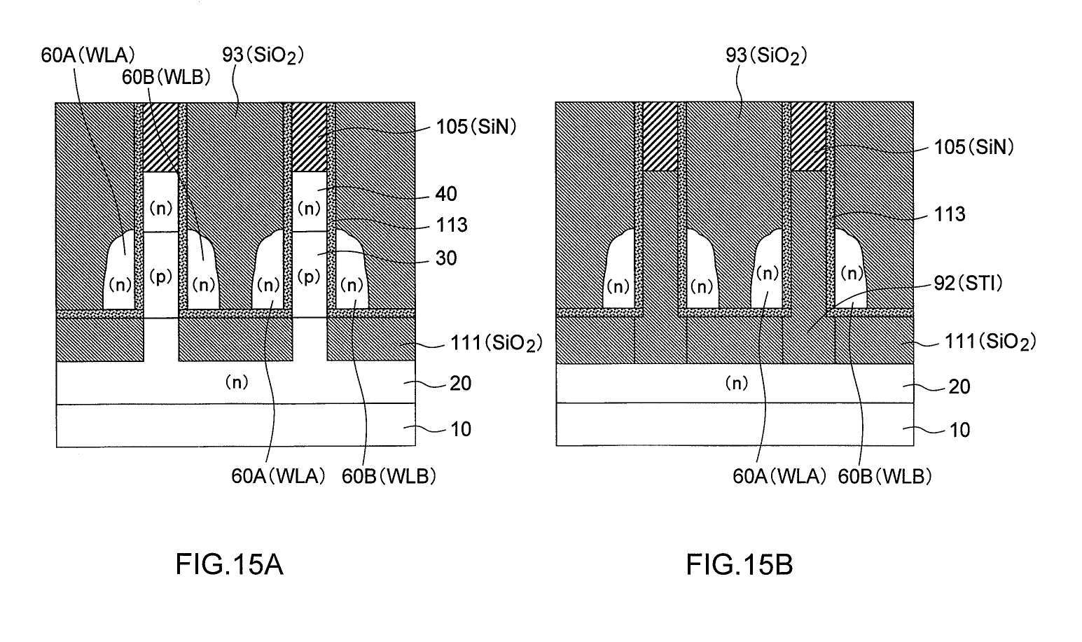

The silicon oxide film 93 is then buried in the trench 109 by a CVD process and its surface is flattened by CMP. In this manner, a configuration shown in FIGS. 15A and 15B can be obtained.

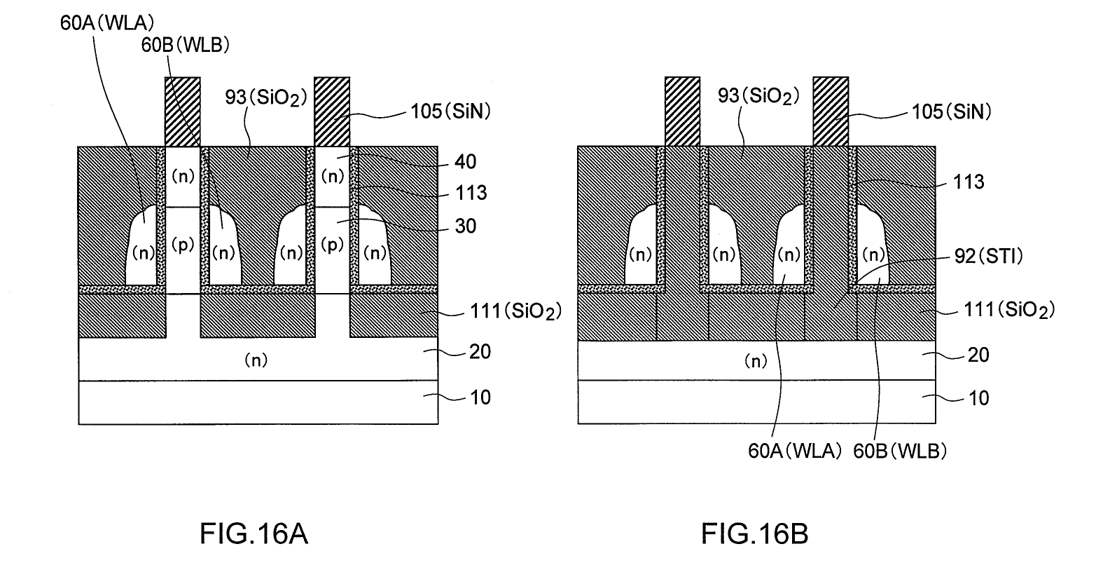

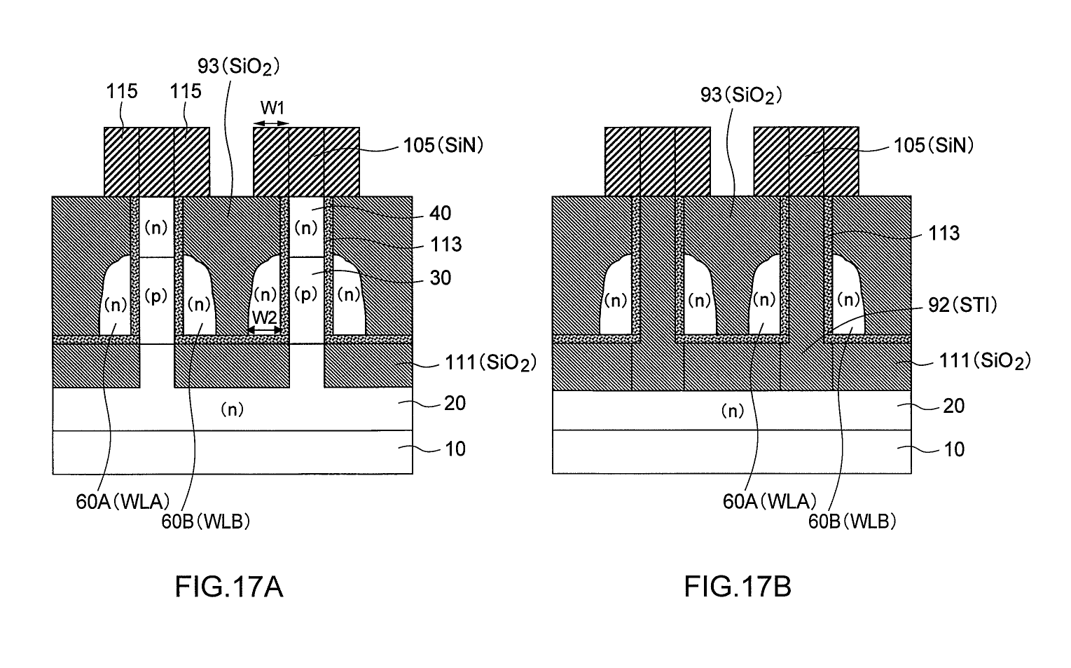

Next, as shown in FIGS. 16A and 16B, the silicon oxide film 93 is etched back so that the silicon nitride film 105 is exposed. As shown in FIGS. 17A and 17B, a silicon nitride film 115 is then deposited on the silicon nitride film 105 and the silicon oxide film 93. Subsequently, the silicon nitride film 115 is anisotropically etched by RIE so as to remain as a sidewall on the side surface of the silicon nitride film 105. At this time, a thickness (width) W1 of the silicon nitride film 115 deposited on the side surface of the silicon nitride film 105 in a transverse direction is desirably slightly smaller than a thickness (width) W2 of the gate electrodes 60A and 60B deposited on the side surface of the ferroelectric film 113 in the transverse direction. This is because parts of surfaces of the gate electrodes 60A and 60B are exposed in a subsequent step so that silicide is formed at the gate electrodes 60A and 60B.

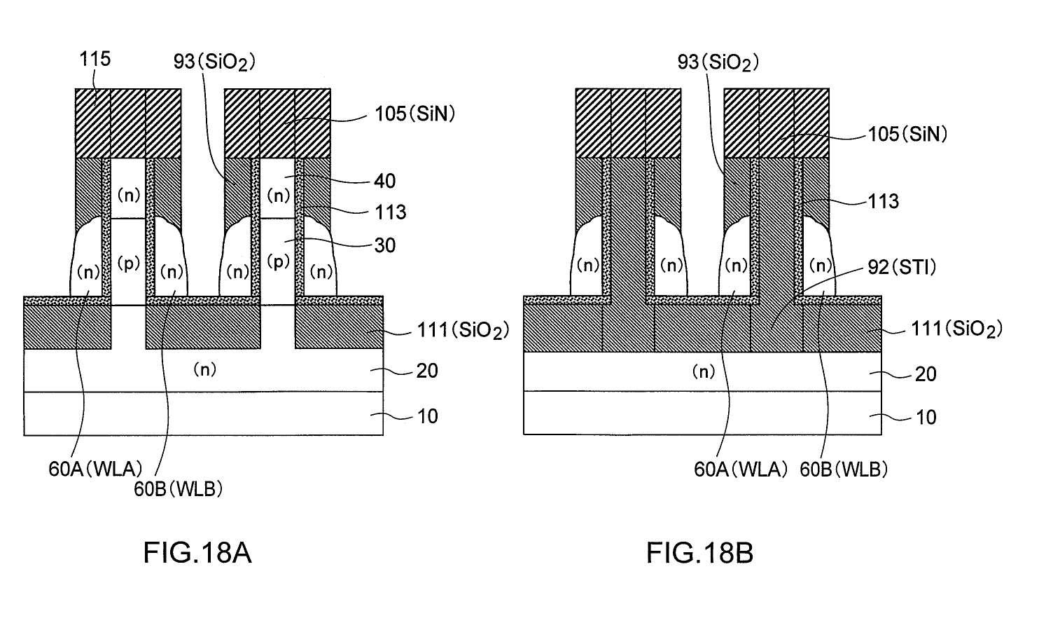

Next, as shown in FIGS. 18A and 18B, the silicon oxide film 93 is anisotropically etched by RIE using the silicon nitride films 105 and 115 as a mask. At this time, because the thickness (width) W1 of the silicon nitride film 115 deposited is slightly smaller than the thickness (width) W2 of the gate electrodes 60A and 60B deposited, only the side surfaces of the gate electrodes 60A and 60B are exposed. The side surface of the drain layer 40 is covered by the ferroelectric film 113. The ferroelectric film 113 is covered and protected by the silicon oxide film 93.

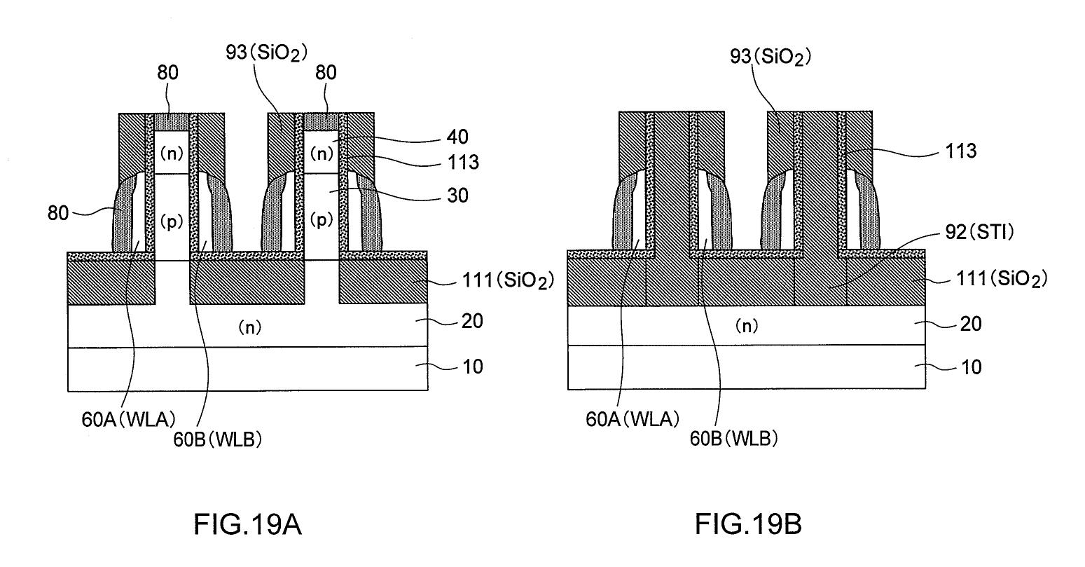

The silicon nitride films 105 and 115 are then removed so that the drain layer 40 is exposed. A metal film (not shown) is deposited on the gate electrodes 60A and 60B and the drain layer 40 and then thermally treated. The metal film is made of titanium, cobalt, or nickel, for example. With this process, as shown in FIGS. 19A and 19B, the silicide layer 80 is formed on the gate electrodes 60A and 60B and the drain layer 40.

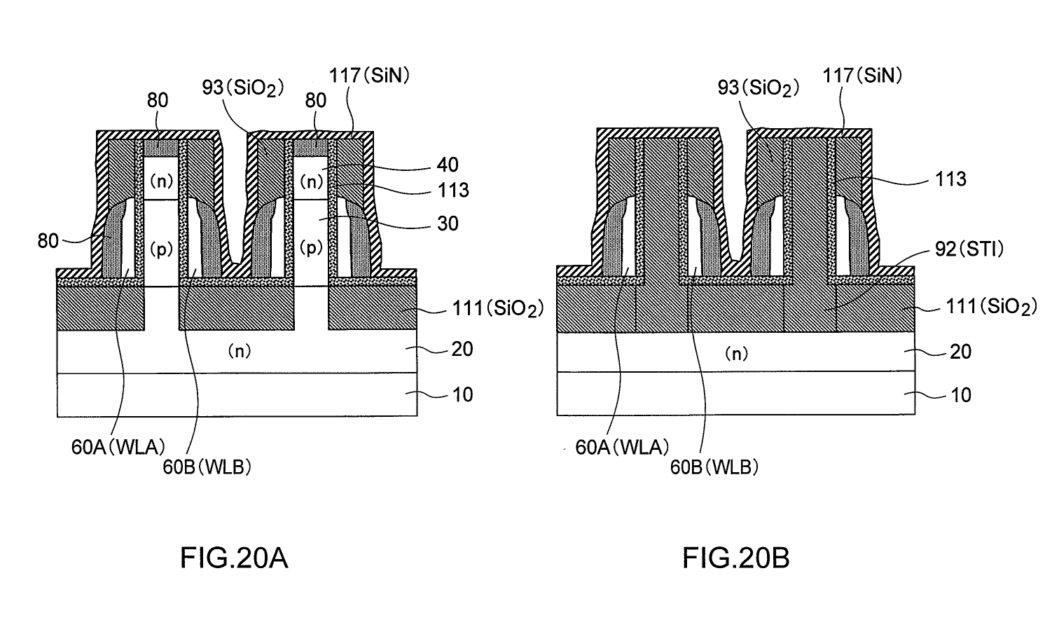

Next, as shown in FIGS. 20A and 20B, a silicon nitride film 117 as a liner film is deposited on the surfaces of the gate electrodes 60A and 60B and the drain layer 40.

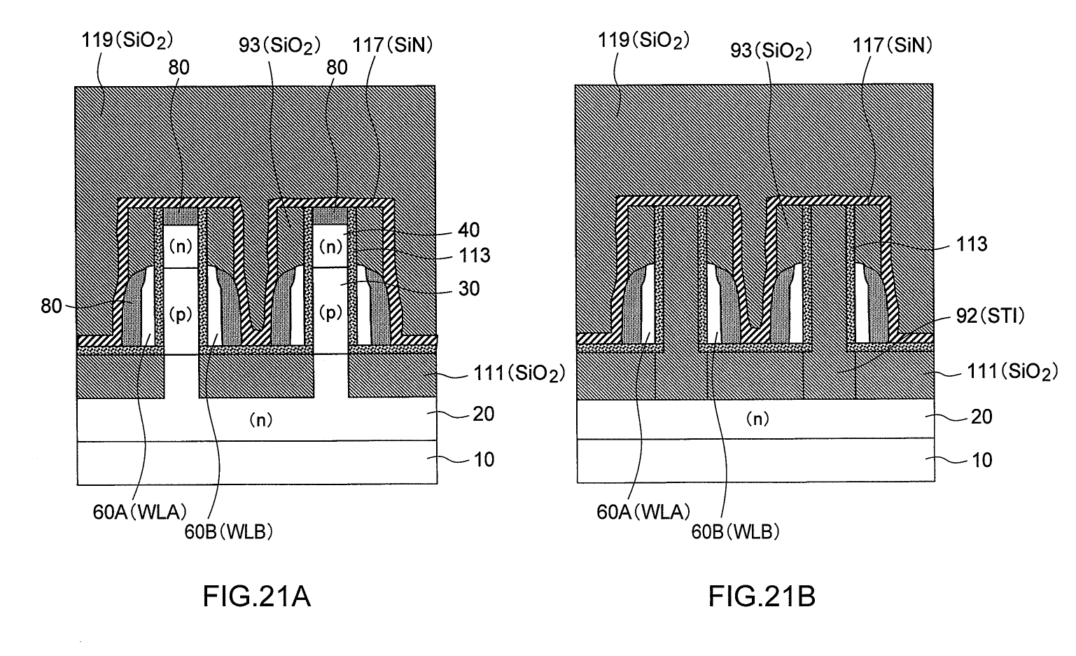

Next, as shown in FIGS. 21A and 21B, a silicon oxide film 119 as an interlayer dielectric film is deposited on the surface of the liner film 117.

Thereafter, the silicon oxide film 119 and the liner film 117 at a part where the bit line BL is to be formed are removed by lithography and RIE. In this manner, a trench reaching the silicide layer 80 on the drain layer 40 is formed at the part where the bit line BL is to be formed. A laminated barrier metal made of a Ti film and a TiN film (not shown) is then deposited in the trench at the part where the bit line BL is to be formed and tungsten is then buried in the trench. With this arrangement, the bit line BL contacting the silicide layer 80 on the drain layer 40 is formed. Thereafter, insulating films and wirings (not shown) are formed if necessary. In this manner, the double gate ferroelectric memory shown in FIGS. 3A and 3B is completed.

### First Modification of First Embodiment

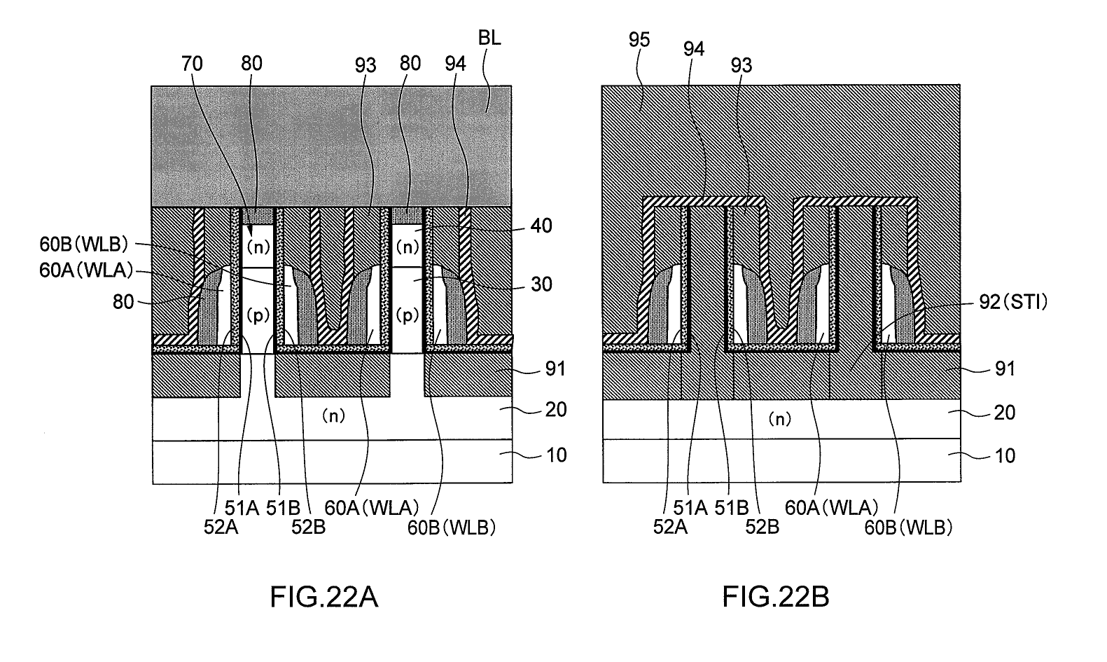

FIGS. 22A and 22B are cross-sectional views of a double gate ferroelectric memory according to a first modification of the first embodiment. The gate dielectric films 50A and 50B as a ferroelectric film are placed so as to contact directly the side surface of the body region 30 in the first embodiment. However, when the ferroelectric film is provided directly on the silicon layer 101, ferroelectric material may diffuse in channels of the body region 30. To prevent such diffusion of the ferroelectric material, first insulating films 51A and 51B made of a paraelectric film (silicon oxide film, HfO₂, Y₂O₃, HfSiON, HfSiO, Ta₂O₅, BaTiO₃, BaZrO₃, ZrO₂, or Al₂O₃) are formed on the side surface of the silicon layer 101 and second insulating films 52A and 52B made of a ferroelectric film with polarization characteristics are then formed on the first insulating films 51A and 51B according to this modification, as shown in FIGS. 22A and 22B. The first gate dielectric film 50A includes the first insulating film 51A made of a paraelectric film between the second insulating film 52A made of a ferroelectric film and one side surface of the body region 30. The second gate dielectric film 50B includes the second insulating film 51B made of a paraelectric film between the second insulating film 52B made of a ferroelectric film and the other side surface of the body region 30.

In this manner, the first insulating films 51A and 51B function as a buffer in process. Accordingly, it is possible to prevent the ferroelectric material from diffusing in the body region 30 in a thermal treatment step. Furthermore, the first insulating films 51A and 51B made of a paraelectric body are provided between the body region 30 and the second insulating film 52A made of a ferroelectric film and between the body region 30 and the second insulating film 52B made of a ferroelectric film, respectively. Reduction of carrier mobility in the body region 30 can be also suppressed.

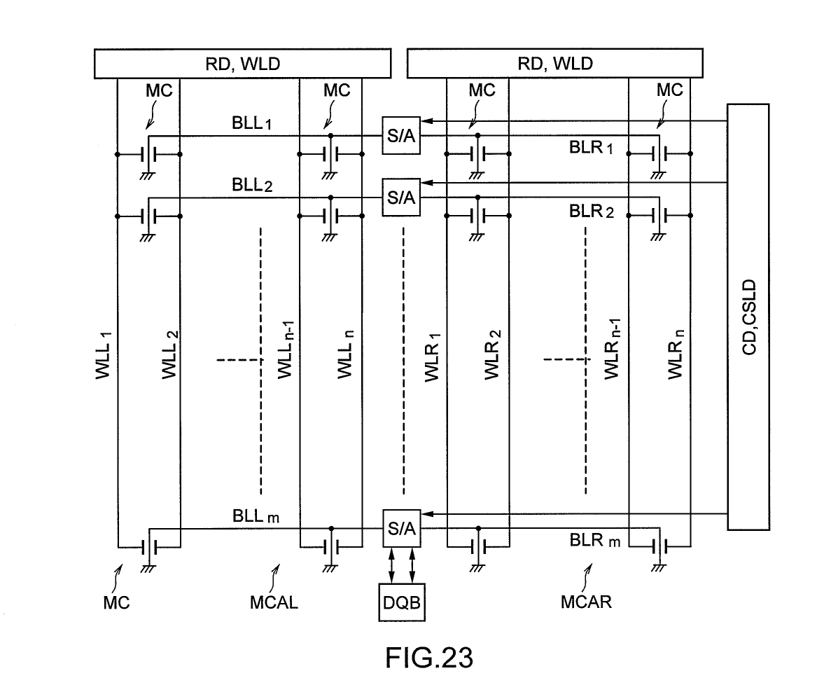

FIG. 23 is a block diagram showing a configuration of cell array and periphery of the double gate ferroelectric memory according to the first embodiment or the first modification. This memory device comprises double-gate memory cells MC, word lines WLL0 to WLLn and WLR0 to WLRn (hereinafter, also WL), bit lines BLL0 to BLLm and BLR0 to BLRm (hereinafter, also BL), sense amplifiers S/A, row decoders RD, WL drivers WLD, a column decoder CD, and a CSL driver CSLD.

The memory cells MC are arranged two-dimensionally in a matrix to constitute memory cell arrays MCAL and MCAR (hereinafter, also MCA). The word line WL extends in the row direction and functions as a gate electrode of the memory cell MC. Two adjacent word lines WL make a pair and the memory cell MC is provided between the pair of word lines. The bit line BL extends in the column direction and is connected to a source or a drain of the memory cell MC. m bit lines BL are provided on the right and the left sides of the sense amplifier S/A. A word line pair WLₖ and WLₖ₊₁ (1≦k≦n−1) crosses a bit line BLⱼ (1≦j≦m) perpendicularly. The row direction and the column direction are called merely for convenience and interchangeable.

The row decoder RD decodes a row address to select a particular word line among the word lines WL. The WL driver WLD applies a voltage to a selected word line to activate the selected word line.

The column decoder CD decodes a column address to select a particular column among a plurality of columns. The CSL driver CSLD applies a potential to a selected column line CSL to read data from the sense amplifier S/A to the DQ buffer DQB. The sense amplifier S/A can read data outside the memory through the DQ buffer DQB. Alternatively, the sense amplifier S/A can write data from the outside of the memory in memory cells through the DQ buffer DQB. The polarity of a voltage indicates a voltage in a positive direction or a negative direction with respect to a reference potential which is a ground potential or a source potential. The polarity of data indicates data “1” or data “0” that are complementary to each other.

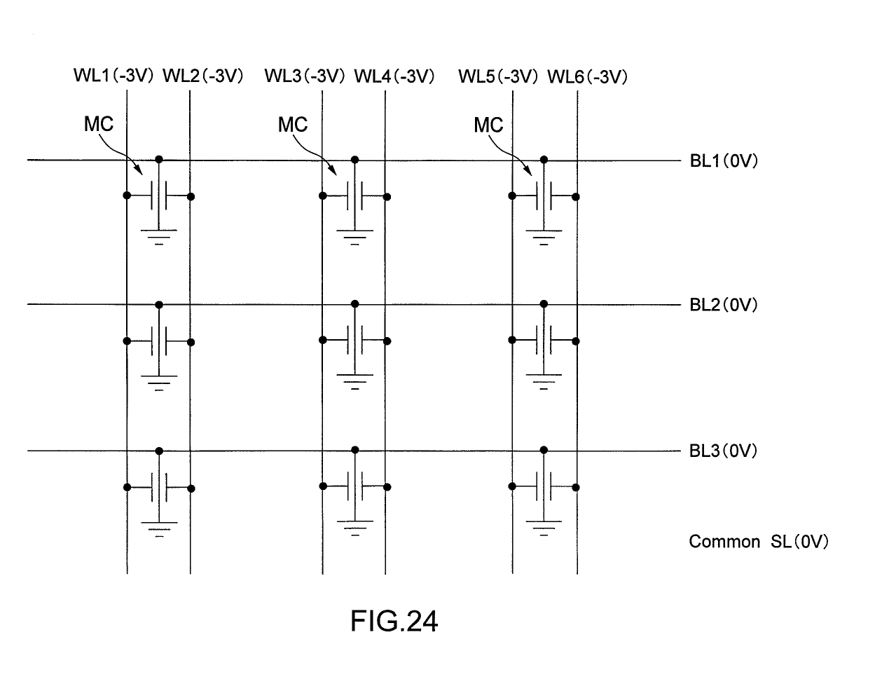

A driving method of a double gate ferroelectric memory according to the first embodiment is described below with reference to FIGS. 24 to 28. FIGS. 24 to 28 are circuit diagrams showing the driving method of a double gate ferroelectric memory according to the first embodiment. Word lines WL1, WL3, and WL5 correspond to the first gate electrode 60A and word lines WL2, WL4, and WL6 correspond to the second gate electrode 60B. This driving method can be applied to the first modification.

### (Write Operation)

In a write operation, as shown in FIG. 24, the WL driver WLD first applies a negative voltage (for example, −3 V) to all the word lines WL1 to WL6 and the CSL driver CSLD applies a reference voltage (for example, 0 V) to all bit lines BL1 to BL3 and to the common source layer 20. With this arrangement, the first gate dielectric films 50A and the second gate dielectric films 50B of all the memory cells MC are made to be in a negative polarization state.

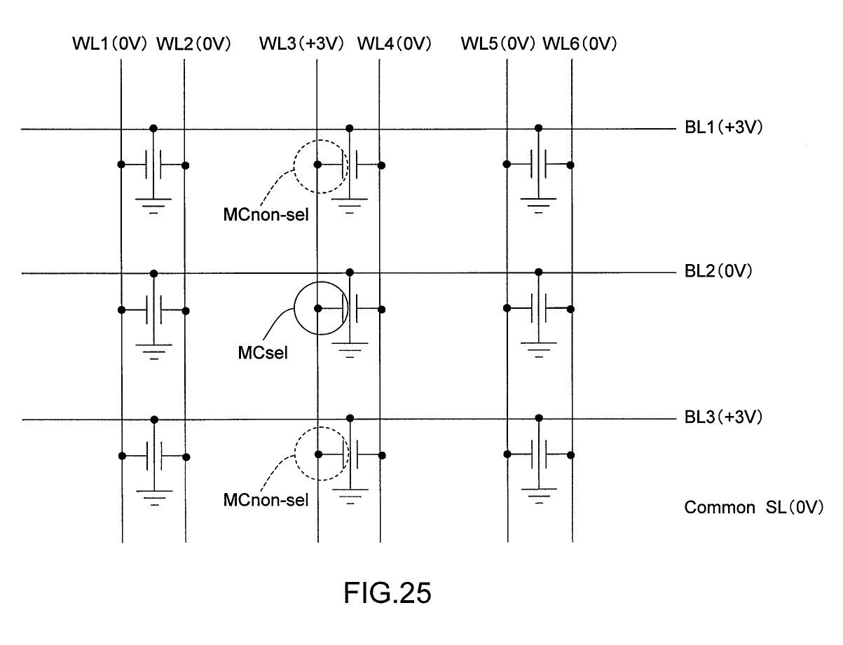

Next, as shown in FIG. 25, the polarization state of one gate dielectric film of a selected memory cell MCsel is inverted. For example, the WL driver WLD applies a positive voltage (for example, +3 V) to the first word line WL3 while setting the voltage of other unselected word lines WL1, WL2, and WL4 to WL6 to the reference voltage. The CSL driver CSLD applies the reference voltage to a selected bit line BL2 and a positive voltage (for example, +3 V) to other unselected bit lines BL1 and BL3. A positive voltage is thus applied to the first gate electrode 60A of the memory cell MCsel shown by a solid line circle in FIG. 25 and the reference voltage (0 V) is applied to the bit line BL2 and the common source layer 20. As a result, the polarization state of the first gate dielectric film 50A of the memory cell MCsel is inverted from negative polarization to positive polarization.

A positive voltage is applied to the first gate electrode 60A in an unselected memory cell MCnon-sel connected to the selected word line WL3 and shown by a broken line circle in FIG. 25. However, the voltage of the bit lines BL1 and BL3 is also a positive voltage. An electric field which is so large as to invert the polarization state of the first gate dielectric film 50A is not applied to the first gate dielectric film 50A of the unselected memory cell MCnon-sel. Because a large electric field is not applied to the first gate dielectric film 50A of the unselected memory cell MCnon-sel, the voltage of the unselected bit lines BL1 and BL3 is preferably equal to or approximates the voltage of the selected word line WL3.

The reference voltage (0 V) is applied to the unselected word line WL4 connected to the second gate electrode 60B of the selected memory cell MCsel. Because the selected bit line BL2 also has the reference voltage, an electric field which is so large as to invert the polarization state of the second gate dielectric film 50B is not applied to the second gate dielectric film 50B of the selected memory cell MCsel.

Further, the unselected word lines WL1, WL2, and WL4 to WL6 have the reference voltage (0 V) and the unselected bit lines BL1 and BL3 have a positive voltage (for example, +3 V). Therefore, an electric field for changing the polarization state of the first and second gate dielectric films 50A and 50B into the negative polarization state is applied to other unselected memory cells MC.

As described above, according to the first embodiment, voltages are applied to the word lines WL1 to WL6 and the bit lines BL1 to BL3 as shown in FIG. 25, so that only the polarization state of the first gate dielectric film 50A of the selected memory cell MCsel can be the positive polarization and the polarization states of the second gate dielectric film 50B of the selected memory cell MCsel and of the gate dielectric films 50A and 50B of the other unselected memory cells can be maintained at the negative polarization. Thus, data can be selectively written in only one of the gate dielectric films 50A and 50B of the memory cell MCsel selected among the memory cells MC.

### (Read Operation)

In a read operation, voltages applied to the word lines WL1 to WL6 and the bit lines BL1 to BL3 are smaller as absolute values than those applied in the write operation so that the polarization state of the gate dielectric films 50A and 50B is not changed.

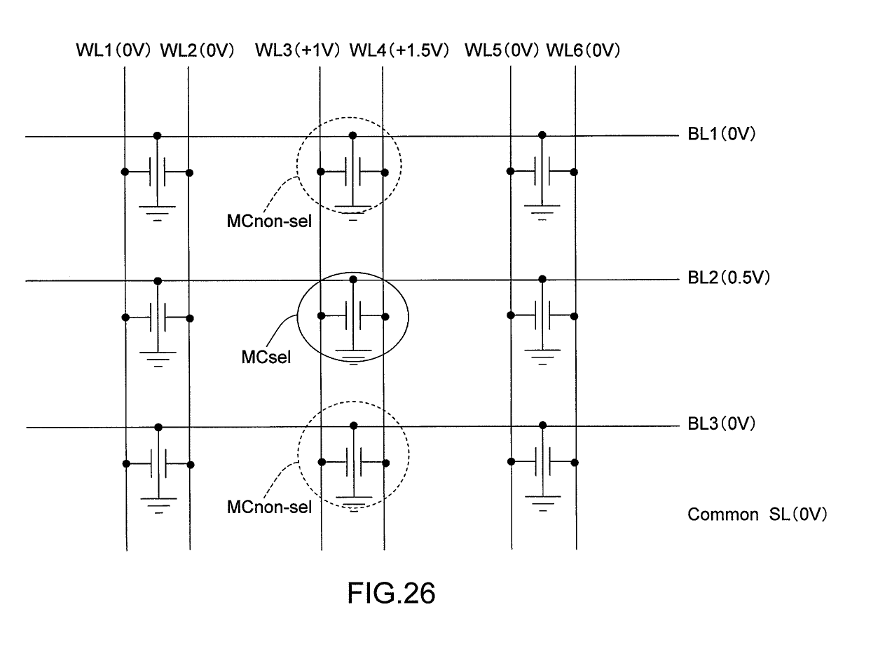

For example, as shown in FIG. 26, the CSL driver CSLD applies a positive voltage (for example, 0.5 V) to the selected bit line BL2. The WL driver WLD applies a first positive voltage (for example, +1 V) to the first gate electrode 60A of the selected memory cell MCsel (the first selected word line WL3) and a second positive voltage (for example, +1.5 V) to the second gate electrode 60B of the selected memory cell MCsel (the second selected word line WL4).

In this manner, the WL driver WLD applies different positive voltages to the first gate electrode 60A and the second gate electrode 60B of the selected memory cell MCsel. The first gate electrode 60A and the second gate electrode 60B of each memory cell MC share the body region 30. Therefore, when a same voltage is applied to the first gate electrode 60A and the second gate electrode 60B of the selected memory cell MCsel, a same current flows in the body region 30 in cases that the polarization state of the first gate electrode 60A and the second gate electrode 60B is (0, 1) and that the polarization state is (1, 0). That is, when the same voltage is applied to the selected word line pair WL3 and WL4, the sense amplifier S/A cannot distinguish data (0, 1) from data (1, 0).

The WL driver WLD thus applies different positive voltages to the first gate electrode 60A and to the second gate electrode 60B of the selected memory cell MCsel in the first embodiment. With this arrangement, different currents flow in the body region 30 in cases that the polarization state of the first gate electrode 60A and the second gate electrode 60B is (0, 1) and that the polarization state is (1, 0). As a result, the sense amplifier S/A can distinguish the data (0, 1) from the data (1, 0).

x in (x, y) indicates the polarization state of the first gate electrode 60A and y in (x, y) indicates the polarization state of the second gate electrode 60B. Note that x or y=0 indicates a negative polarization and x or y=1 indicates a positive polarization.

According to the first embodiment, the current flowing in the body region 30 of the selected memory cell MCsel is maximized in the case of (0, 0). As the threshold voltage of a transistor in a memory cell is increased due to the positive polarization, the current flowing in the body region 30 of the selected memory cell MCsel becomes reduced in the order of (1, 0), (0, 1), and (1, 1). Thus, the sense amplifier S/A can identify (0, 0), (1, 0), (0, 1), and (1, 1). That is, each memory cell MC of the double gate ferroelectric memory according to the first embodiment can store and read 2-bit data.

Because the voltage of the bit lines BL1 and BL3 and the voltage of the source layer 20 are the same, that is, the reference voltage in the unselected memory cell MCnon-sel connected to the selected word line pair WL3 and WL4, data is not read from the unselected memory cell MCnon-sel. Because the word lines WL1, WL2, WL5, and WL6 have the reference voltage in other unselected memory cells, these memory cells MC are not switched on. Accordingly, data is not read from the unselected memory cells and only the data of the selected memory cell MCsel is read.

The driving method described above can be applied to the first modification of the first embodiment.

### Second Modification of First Embodiment

A second modification of the first embodiment is different from the first embodiment in the data write operation. The polarization states of the gate dielectric films 50A and 50B of all the memory cells MC are made first to be the negative polarization state and then the polarization state of the gate dielectric film 50A or 50B of the selected memory cell MCsel is selectively made to be the positive polarization state in the first embodiment. On the other hand, in the second modification, the polarization states of the gate dielectric films 50A and 50B of all the memory cells MC are made to be the positive polarization state and then the polarization state of the gate dielectric film 50A or 50B of the selected memory cell MCsel is selectively made to be the negative polarization state.

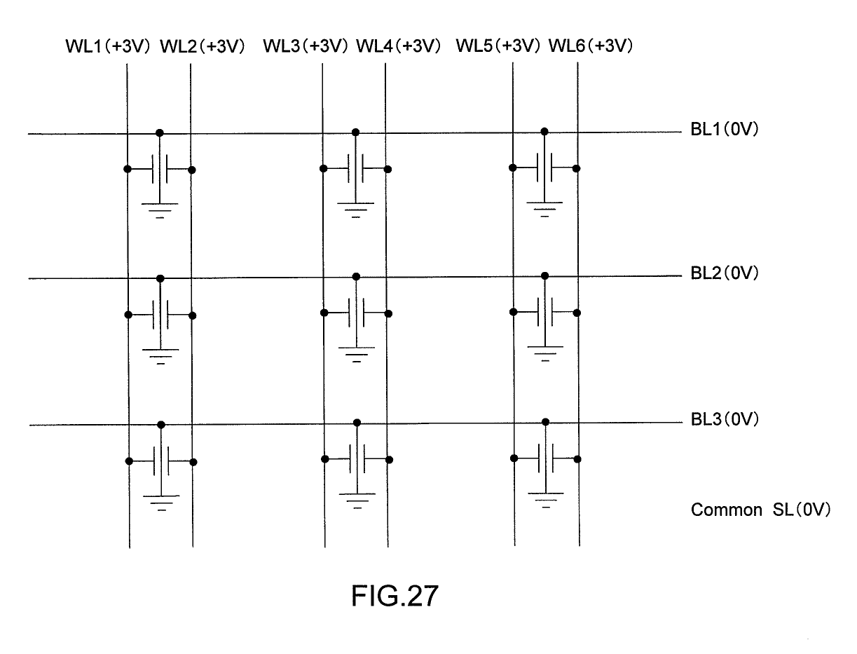

First, as shown in FIG. 27, the WL driver WLD applies a positive voltage (for example, +3 V) to all the word lines WL1 to WL6 and the CSL driver CSLD applies the reference voltage (for example, 0 V) to all bit lines BL1 to BL3 and to the common source layer 20. The first gate dielectric films 50A and the second gate dielectric films 50B of all the memory cells MC are thus made to be the positive polarization.

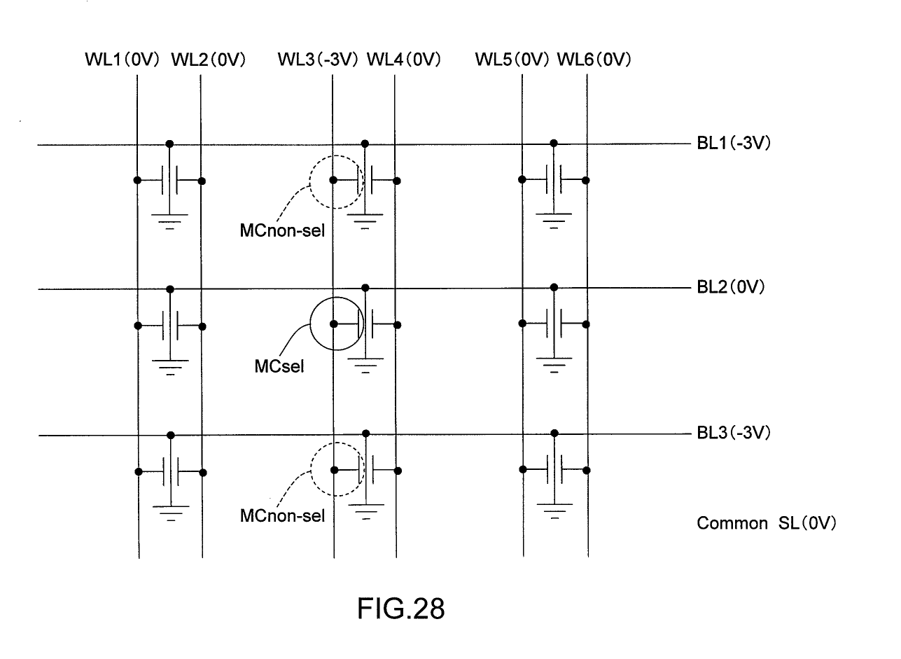

Next, as shown in FIG. 28, the polarization state of one gate dielectric film 50A of the selected memory cell MCsel is inverted. For example, the WL driver WLD applies a negative voltage (for example, −3 V) to the first word line WL3 while setting the voltage of other unselected word lines WL1, WL2, and WL4 to WL6 to the reference voltage. The CSL driver CSLD applies the reference voltage to a selected bit line BL2 and a negative voltage (for example, −3 V) to other unselected bit lines BL1 and BL3. A negative voltage is thus applied to the first gate electrode 60A of the memory cell MCsel shown by a solid line circle in FIG. 28 and the reference voltage (0 V) is applied to the bit line BL2 and the common source layer 20. As a result, the polarization state of the first gate dielectric film 50A of the memory cell MCsel is inverted from the positive polarization to the negative polarization.

A negative voltage is applied to the first gate electrode 60A of the unselected memory cell MCnon-sel connected to the selected word line WL3 and shown by a broken line circle in FIG. 28. However, as the voltage of the bit lines BL1 and BL3 is also a negative one, an electric field which is so large as to invert the polarization state of the first gate dielectric film 50A is not applied to the first gate dielectric film 50A of the unselected memory cell MCnon-sel. The voltage of the unselected bit lines BL1 and BL3 is preferably equal to or approximates the voltage of the selected word line WL3 because a large electric field is not applied to the first gate dielectric film 50A of the unselected memory cell MCnon-sel.

The reference voltage (0 V) is applied to the unselected word line WL4 connected to the second gate electrode 60B of the selected memory cell MCsel. As the selected bit line BL2 also has the reference voltage, an electric field which is so large as to invert the polarization state of the second gate dielectric film 50B is not applied to the second gate dielectric film 50B of the selected memory cell MCsel.

Further, the unselected word lines WL1, WL2, and WL4 to WL6 have the reference voltage (0 V) and the unselected bit lines BL1 and BL3 have a negative voltage (for example, −3 V). Accordingly, an electric field changing the polarization state of the first and second gate dielectric films 50A and 50B into the positive polarization is applied to other unselected memory cells MC.

As described above, voltages are applied to the word lines WL1 to WL6 and the bit lines BL1 to BL3 as shown in FIG. 28, so that only the polarization state of the first gate dielectric film 50A of the selected memory cell MCsel can be the negative polarization and the polarization states of the second gate dielectric film 50B of the selected memory cell MCsel and of the gate dielectric films 50A and 50B of other unselected memory cells can be maintained at the positive polarization in the first embodiment. In this manner, data can be selectively written in only one of the gate dielectric films 50A and 50B of the memory cell MCsel selected among the memory cells MC.

The read operation of the second modification can be identical to the read operation of the first embodiment shown in FIG. 26.

The second modification can be combined with the first modification.

### Second Embodiment

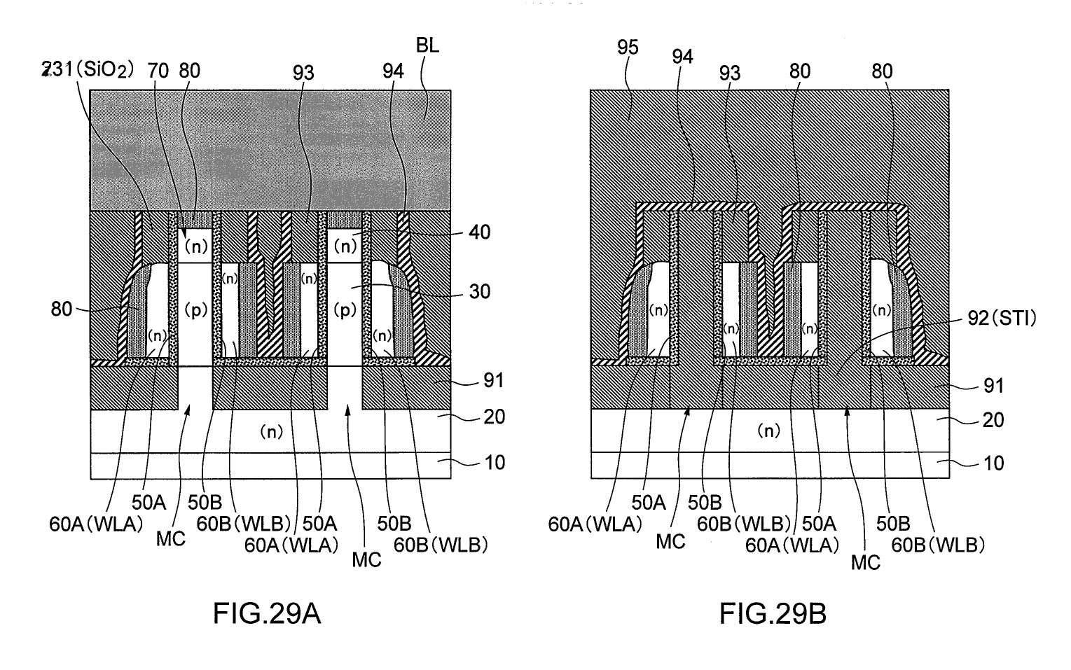

FIGS. 29A and 29B are cross-sectional views showing a configuration of a double gate ferroelectric memory according to a second embodiment of the present invention. The plan view of the second embodiment is substantially the same as FIG. 2, and thus explanations thereof will be omitted.

The configuration of the double gate ferroelectric memory according to the second embodiment is basically the same as that of the double gate ferroelectric memory according to the first embodiment (or the first modification). Further, a driving method of a double gate ferroelectric memory according to the second embodiment is the same as that of a double gate ferroelectric memory according to the first embodiment (or the second modification).

However, in the second embodiment, the gate dielectric films 50A and 50B on both sides of the body region 30 are formed by different steps and the gate electrodes 60A and 60B are also formed by different steps. Therefore, thickness and material of the first gate dielectric film 50A can be different from those of the second gate dielectric film 50B in the second embodiment. Thickness, impurity density, material, and shape of the first gate electrode 60A can be different from those of the second gate electrode 60B.

The gate dielectric films 50A and 50B adjacent to each other between two adjacent body regions 30 (on one side of the body regions 30) are formed by a same step. The gate electrodes 60A and 60B adjacent to each other between two adjacent body regions 30 are formed by a same step.

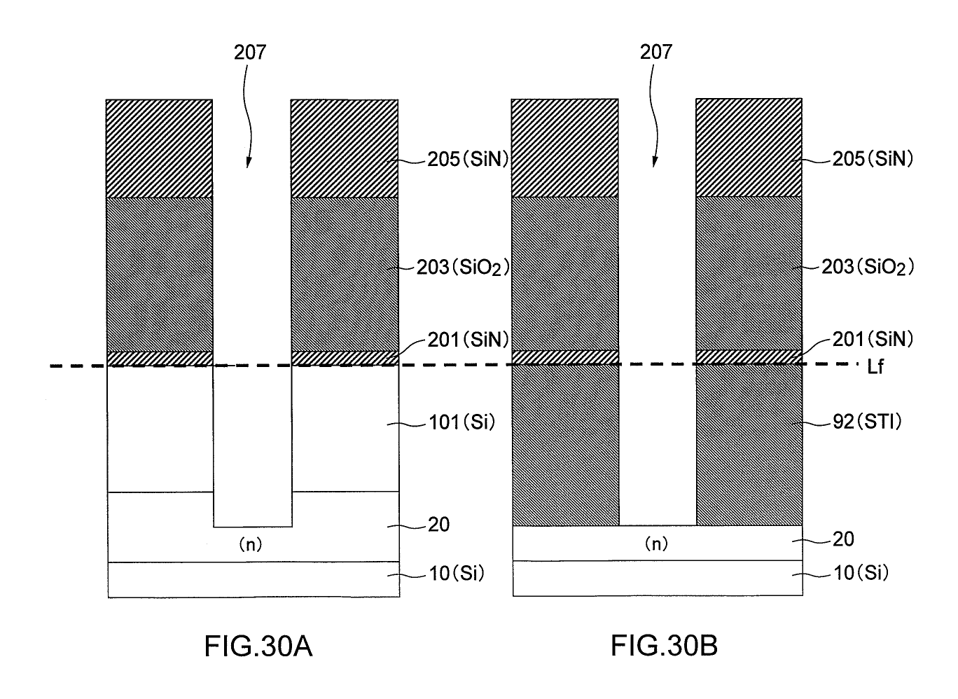

FIGS. 30A to 50B are cross-sectional views showing a manufacturing method of the double gate vertical ferroelectric memory according to the second embodiment. First, as described with reference to FIGS. 4 and 5, a common source layer 20, the silicon layer 101, and the STI 92 are formed on the silicon substrate 10.

A silicon nitride film 201, a silicon oxide film 203, and a silicon nitride film 205 are then deposited on the silicon layer 101 and on the STI 92 shown in FIGS. 5A and 5B. The silicon nitride film 201, the silicon oxide film 203, and the silicon nitride film 205 are then processed by lithography and RIE. With this process, the silicon nitride film 201, the silicon oxide film 203, and the silicon nitride film 205 are formed in stripes so as to extend in a row direction perpendicular to a direction that the silicon layer 101 and the STI 92 extend. Further, a trench 207 extending in the row direction is formed in the silicon nitride film 201, the silicon oxide film 203, and the silicon nitride film 205. The trench 207 is formed so as to reach the silicon layer 101. Next, the silicon layer 101 is etched by RIE using the silicon nitride film 201, the silicon oxide film 203, and the silicon nitride film 205 as a mask. At this time, the trench 207 is formed so as to reach the source layer 20. The bottom surface of the trench 207 is preferably as high as that of the STI 92. In this manner, a configuration shown in FIGS. 30A and 30B is obtained. A broken line Lf indicates the level of surfaces of the silicon layer 101 and the STI 92.

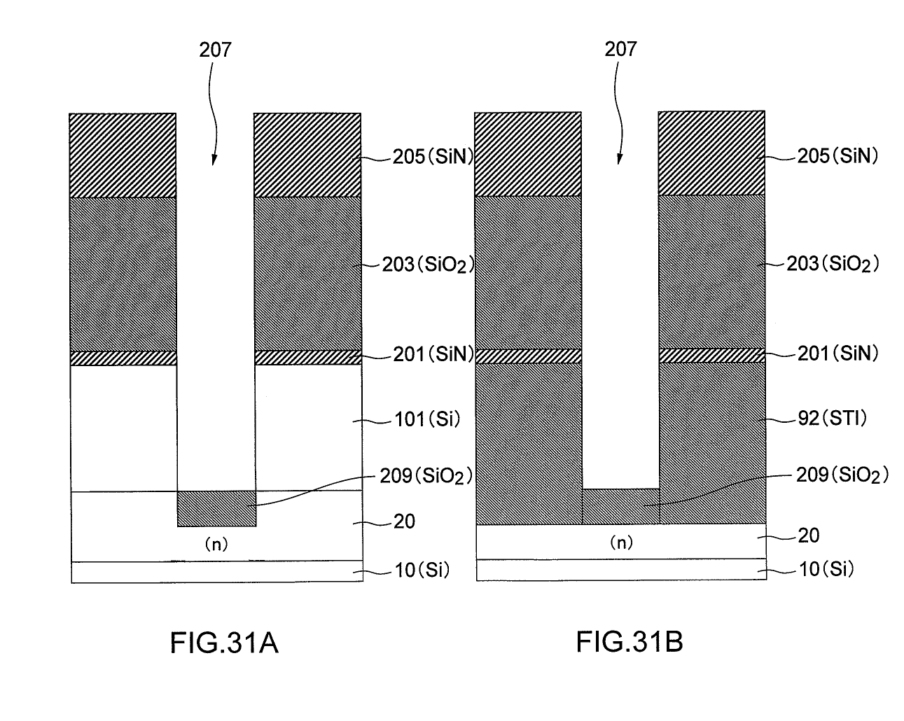

A silicon oxide film 209 is then deposited so that the trench 207 is filled with the silicon oxide film 209. Subsequently, the silicon oxide film 209 is etched back so as to remain at the bottom of the trench 207. As shown in FIG. 31A and FIG. 31B, the top surface of the silicon oxide film 209 is preferably as high as or approximates the boundary between the source layer 20 and the silicon layer 101.

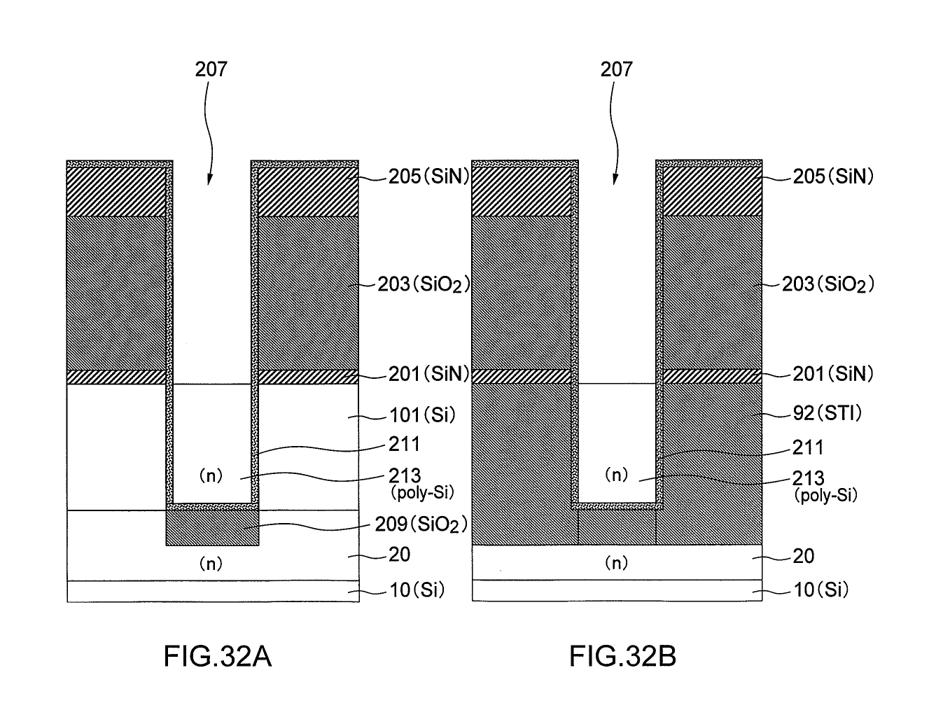

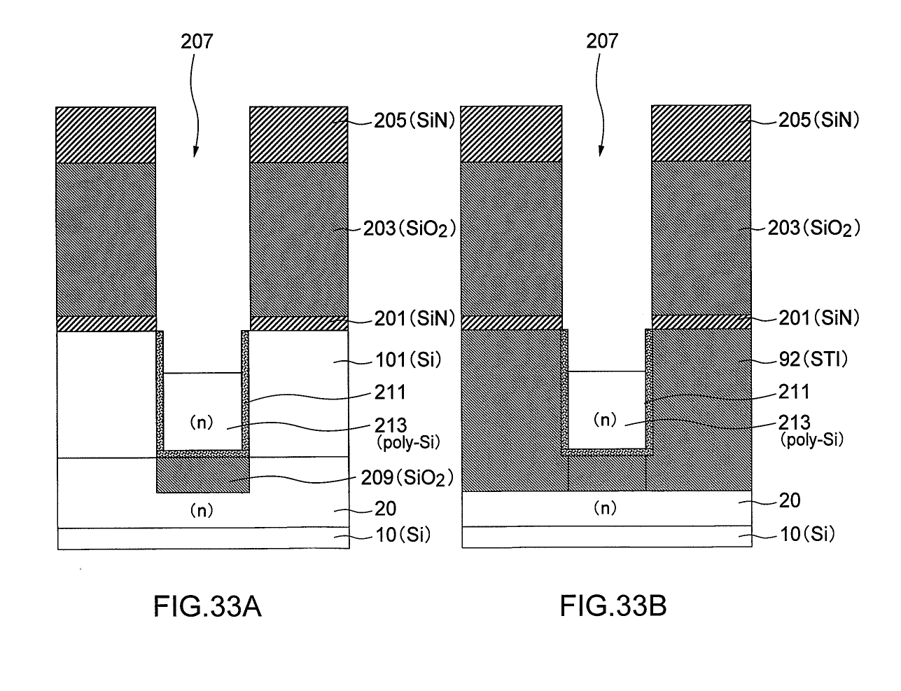

Next, as shown in FIGS. 32A and 32B, a ferroelectric film 211 which becomes the first and second gate dielectric films 50A and 50B is deposited by a CVD process on the inner wall of the trench 207 and on the silicon nitride film 205. At this time, the thickness of the ferroelectric film 211 deposited must be less than ½ of width of the trench 207 in a column direction cross-section so that the trench 207 is not filled with the ferroelectric film 211. Subsequently, polysilicon is deposited while doping an N-type impurity (phosphorus or arsenic) so that the trench 207 is filled with a doped polysilicon layer 213. The doped polysilicon layer 213 becomes a part of the first and second gate electrodes 60A and 60B by a subsequent step. The doped polysilicon layer 213 is then selectively etched back so as to remain in the trench 207. As shown in FIGS. 32A and 32B, the top surface of the polysilicon layer 213 is preferably as high as or approximates the top surface of the silicon layer 101. With this arrangement, the ferroelectric film 211 can be etched by using the polysilicon layer 213 as a mask so as to remain only on the side surface of the silicon layer 101 in the trench 207. The ferroelectric film 211 is etched by a solution containing hydrogen fluoride. Further etching of the polysilicon layer 213 enables the top surface of the polysilicon layer 213 to be as high as the top surface of the body region 30 to be formed in a subsequent step. That is, the top surface of the polysilicon layer 213 is made to be as high as the top surface of a polysilicon layer 229 to be formed in a subsequent step. In this manner, a configuration shown in FIGS. 33A and 33B is obtained.

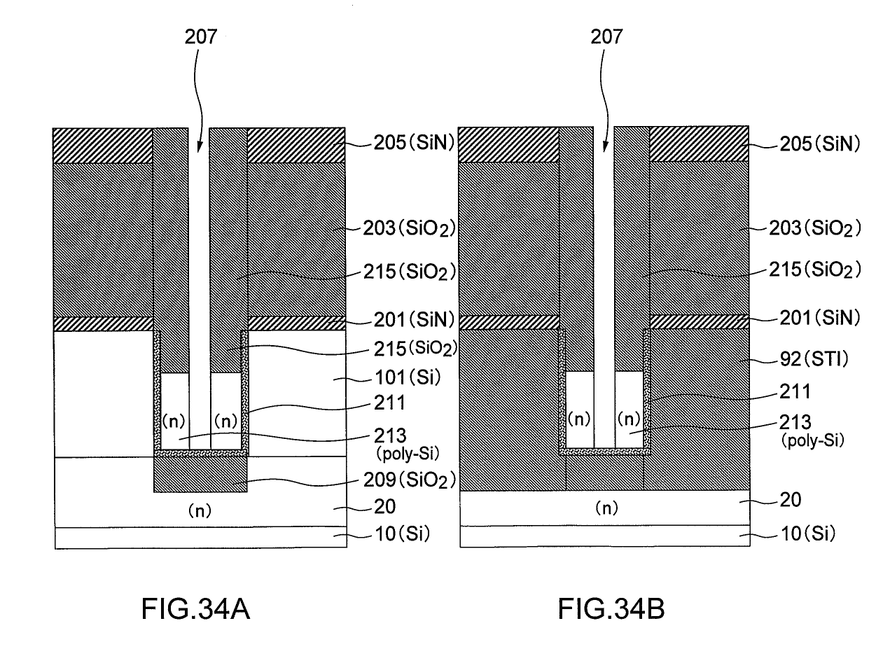

A silicon oxide film 215 is then deposited on the inner wall of the trench 207 and on the silicon nitride film 205. At this time, as shown in FIGS. 34A and 34B, the thickness of the silicon oxide film 215 deposited is less than ½ of width of the trench 207 in a column direction cross-section so that the silicon oxide film 215 does not close an opening of the trench 207. Subsequently, the silicon oxide film 215 is etched back so as to remain only on the inner side surface of the trench 207. At this time, the top surface of the polysilicon layer 213 is exposed. The polysilicon layer 213 is then etched by RIE using the silicon oxide film 215 as a mask. In this manner, as shown in FIGS. 34A and 34B, the polysilicon layer 213 within each trench 207 is divided in the column direction cross-section.

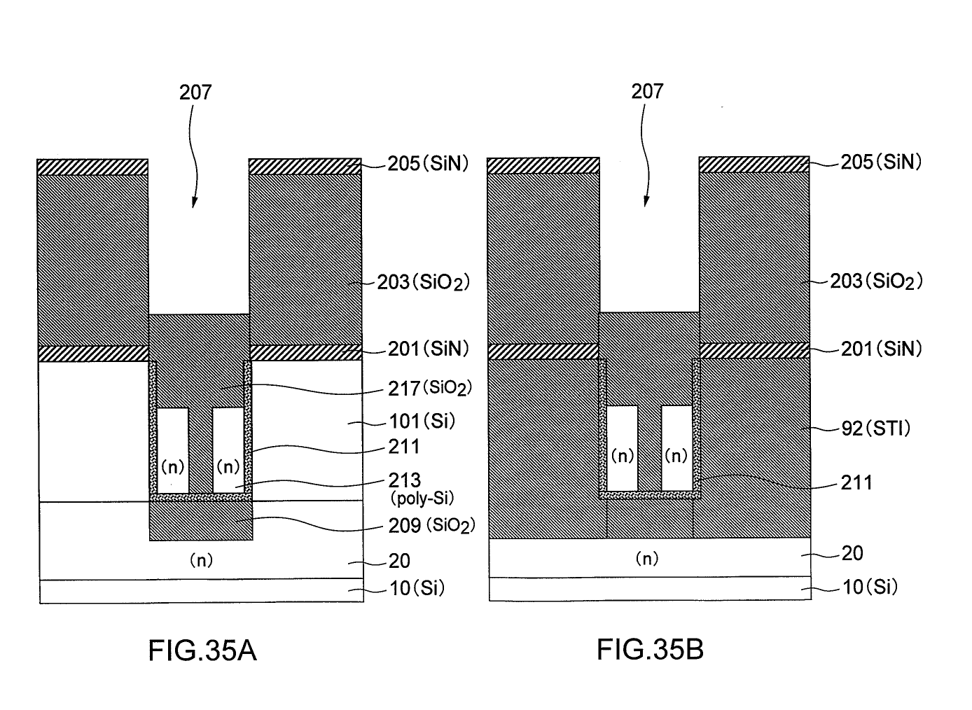

Next, as shown in FIGS. 35A and 35B, a silicon oxide film 217 is charged within the trench 207 and then selectively etched back. The top surface of the silicon oxide film 217 is adjusted so as to be higher than the top surface of the silicon nitride film 201 by about 50 to 100 nm. In this manner, only the side surface of the polysilicon layer 213 can be silicided in a subsequent step.

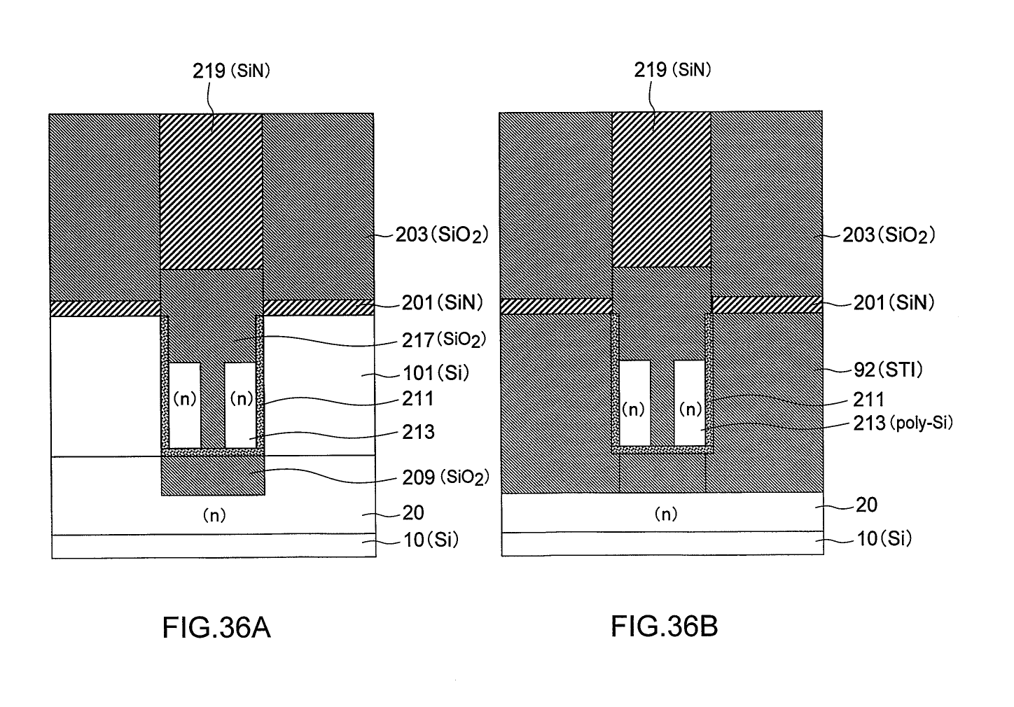

Next, as shown in FIGS. 36A and 36B, a silicon nitride film 219 is buried in the trench 207 by a CVD process and then ground by CMP until the surface of the silicon oxide film 203 is exposed.

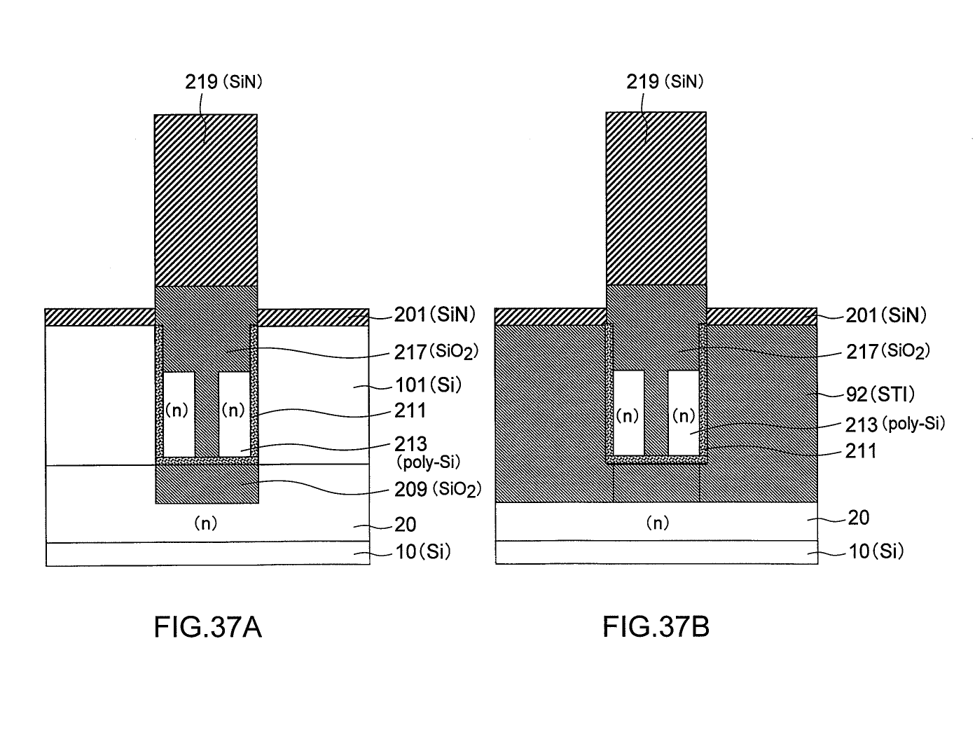

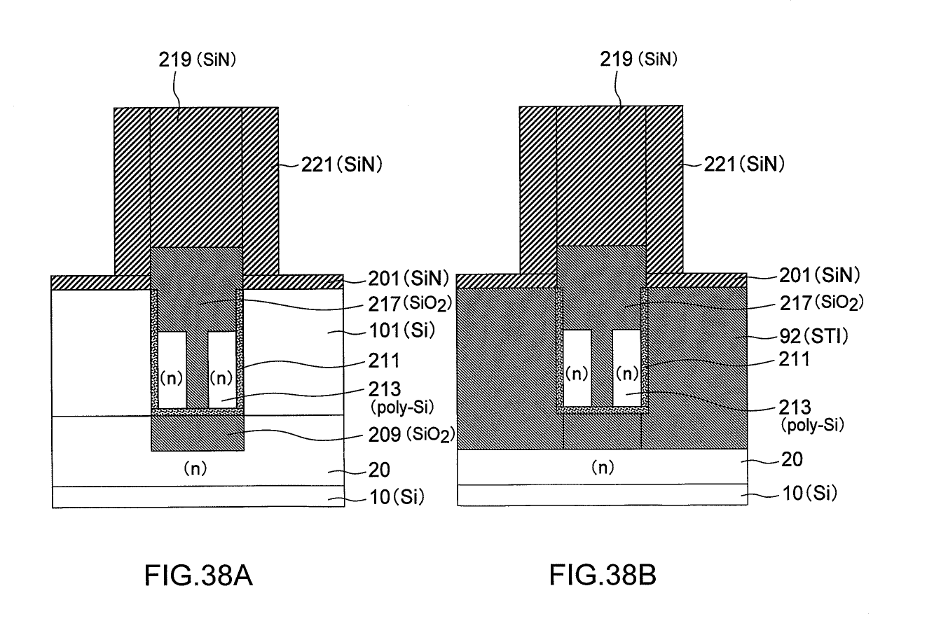

Next, as shown in FIGS. 37A and 37B, the silicon nitride film 219 is etched back by RIE until the surface of the silicon oxide film 203 is exposed. As shown in FIGS. 38A and 38B, a silicon nitride film 221 is deposited on the side surface of the silicon nitride film 219, on the top surface of the silicon nitride film 201, and on the side surface of the silicon oxide film 217 by LP-CVD (Low Pressure-CVD) and then anisotropically etched by RIE. The silicon nitride film 221 thus remains as a sidewall on the side surfaces of the silicon nitride film 219 and the silicon oxide film 217. The column direction width of the silicon nitride film 221 is a factor for determining the column direction width of the vertical body region 30 to be formed in a subsequent step. That is, it can be said that the column direction width of the body region 30 is determined depending on the thickness of the silicon nitride film 221 deposited.

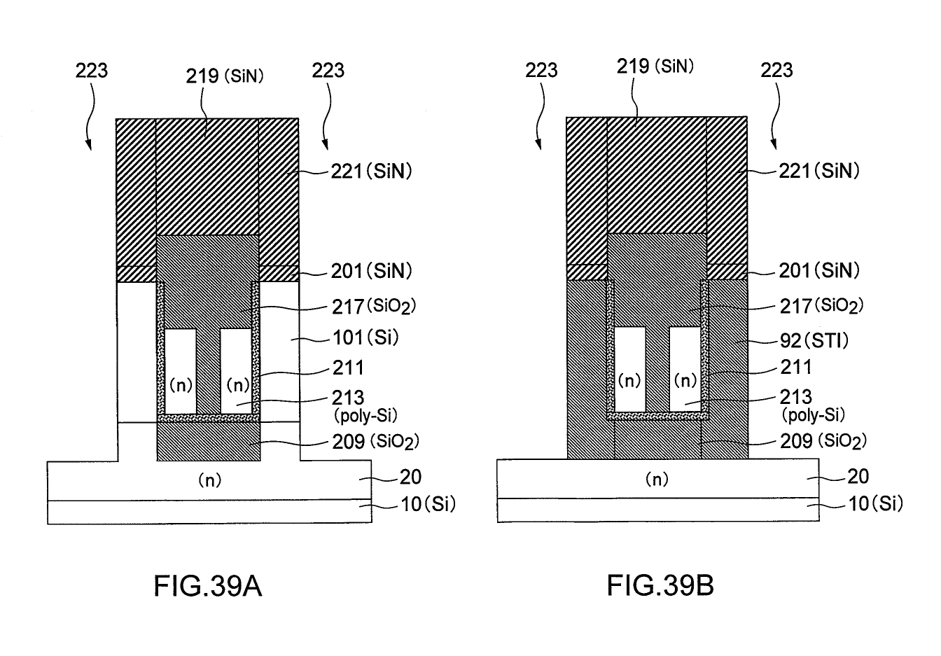

Next, as shown in FIGS. 39A and 39B, the silicon layer 101 and the STI 92 are etched by RIE using the silicon nitride films 219 and 221 as a mask. At this time, because a cross-sectional configuration shown in FIGS. 39A and 39B is formed repeatedly in the column direction, a trench 223 is formed between a plurality of silicon layers 101 and between a plurality of STIs 92 that are adjacent to each other in the column direction. The trench 223 is formed so as to reach the source layer 20. The depth of the trench 223 is almost the same as that of the trench 207.

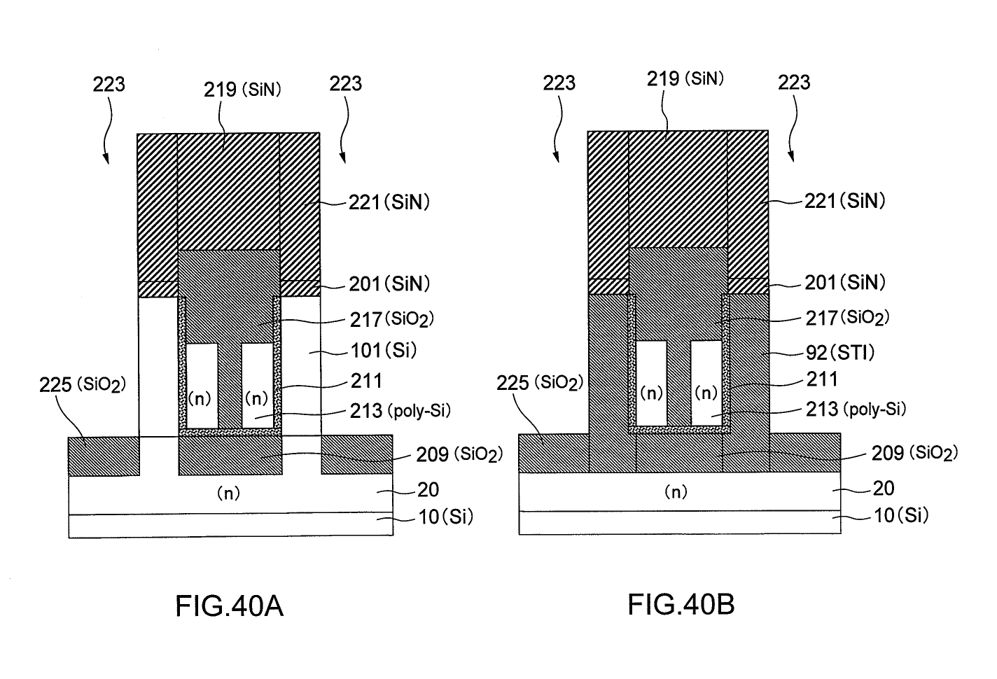

Next, a silicon oxide film 225 is charged within the trench 223 and etched back. In this manner, as shown in FIGS. 40A and 40B, the silicon oxide film 225 is formed at the bottom of the trench 223. The top surface of the silicon oxide film 225 can be substantially as high as the top surface of the silicon oxide film 209.

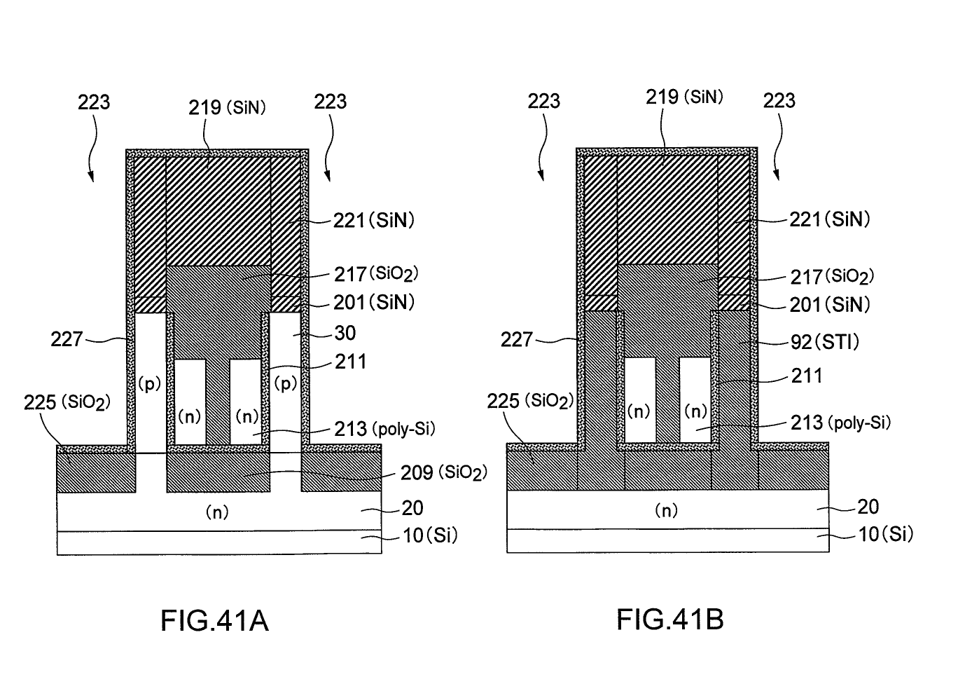

A P-type impurity is then implanted in the silicon layer 101 by oblique ion implantation and thus the P-type silicon layer 101 which becomes the P-type body region 30 is formed as shown in FIG. 41A and FIG. 41B. A ferroelectric film 227 is then deposited on the inner surface of the trench 223. At this time, the thickness of the ferroelectric film 227 must be less than ½ of the column direction width of the trench 223 so that the trench 223 is not completely filled.

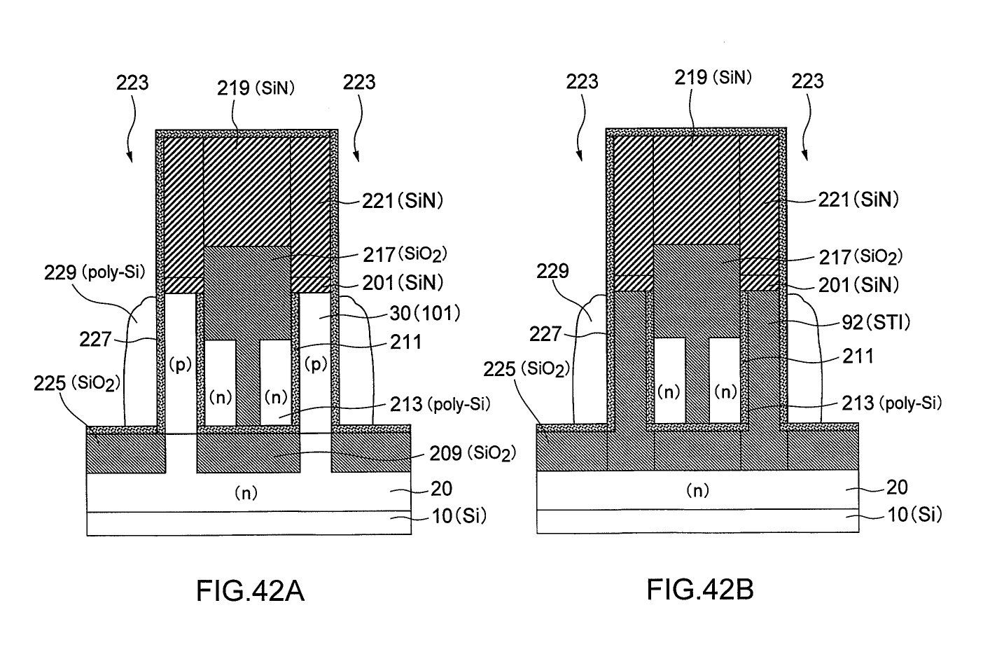

Next, the polysilicon layer 229 is deposited on the ferroelectric film 227 and then isotropically etched back. With this process, as shown in FIGS. 42A and 42B, the polysilicon film 229 is thus formed on the side surface of the silicon layer 101 (the body region 30) with the ferroelectric film 227 interposed therebetween. The thickness of the polysilicon layer 229 deposited is less than ½ of the column direction width of the trench 223 at that time so that the trench 223 is not completely filled. After the etching back, the polysilicon layer 229 is substantially as high as the top surface of the silicon layer 101.

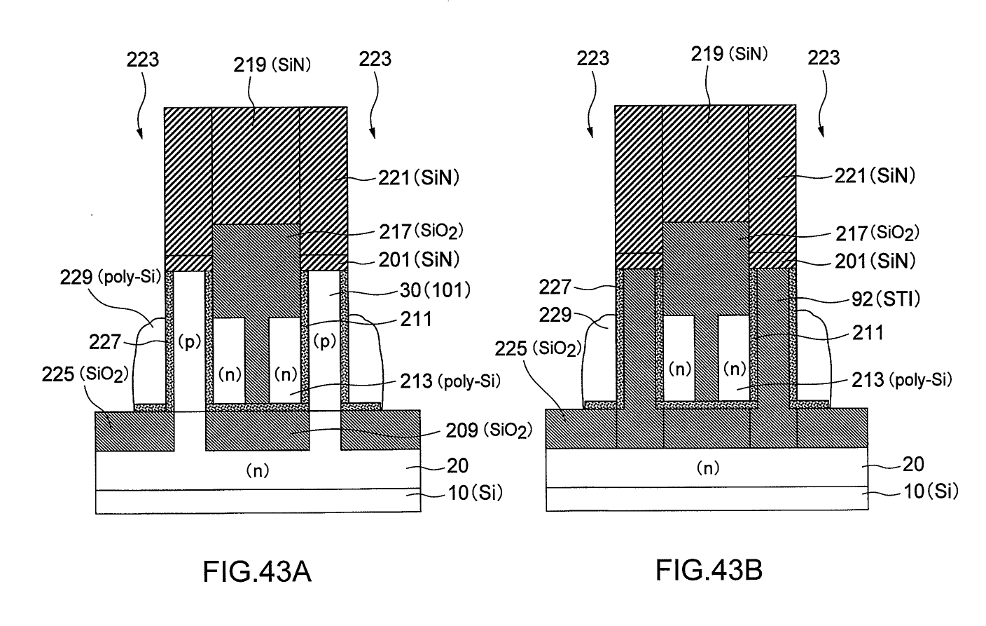

The ferroelectric film 227 deposited on the silicon nitride films 219 and 221 and on the silicon oxide film 225 is then etched with a solution of hydrogen fluoride by using the polysilicon 229 as a mask. Furthermore, to make the height of the polysilicon layer 229 be substantially the same as that of the polysilicon layer 213, the polysilicon layer 229 is etched by RIE. With this process, a configuration shown in FIGS. 43A and 43B is obtained. The polysilicon 229 not only becomes the first and second gate electrodes 60A and 60B in a subsequent step but also is used for determining the length of the body region 30 and the drain layer 40 (a height from surface of silicon substrate 10).

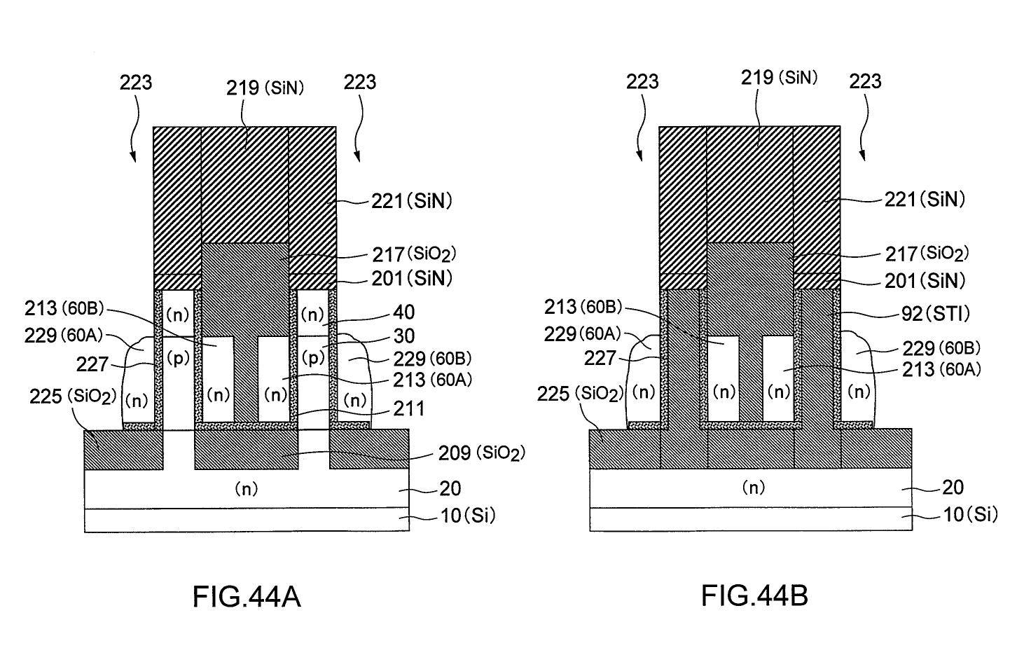

Next, as shown in FIGS. 44A and 44B, an N-type impurity is implanted in the silicon layer 101 by oblique implantation using the polysilicon layer 229 as a mask, so that the N-type drain layer 40 is formed in the silicon layer 101. At the same time, an N-type impurity is also implanted in the polysilicon layer 229 and a part of the first and second gate electrodes 60A and 60B (the word lines WLA and WLB) is thus formed. The polysilicon layers 213 and 229 constitute all the first and second gate electrodes 60A and 60B. A pair of the word lines WLA and WLB that the first gate electrode 60A made of the polysilicon layer 229 and the second gate electrode 60B made of the polysilicon layer 213 are provided on both sides of the body region 30 is thus provided. Further, a pair of the word lines WLA and WLB that the first gate electrode 60A made of the polysilicon layer 213 and the second gate electrode 60B made of the polysilicon layer 229 are provided on both sides of the body region 30 is provided. According to the second embodiment, the gate electrodes 60A and 60B on both sides of each body region 30 are formed individually. Accordingly, the gate electrodes 60A and 60B on both sides of each body region 30 can be made of different materials, be formed in different shapes, or have different impurity densities. Because characteristics of the first gate electrode 60A are different from those of the second gate electrode 60B, data (0, 1) and data (1, 0) stored in the memory cell MC can be easily distinguished from each other.

At the time of forming the N-type drain layer 40, an impurity is simultaneously implanted in a vertical direction in the silicon oxide film 225, so that an N-type impurity can be implanted in the gate electrodes 60A and 60B and in the source layer 20 using scattering in the silicon oxide film 225. That is, implanting an impurity in the gate electrodes 60A and 60B and forming the source layer 20 can be performed in a self-aligned manner by using the gate electrodes 60A and 60B as a mask.

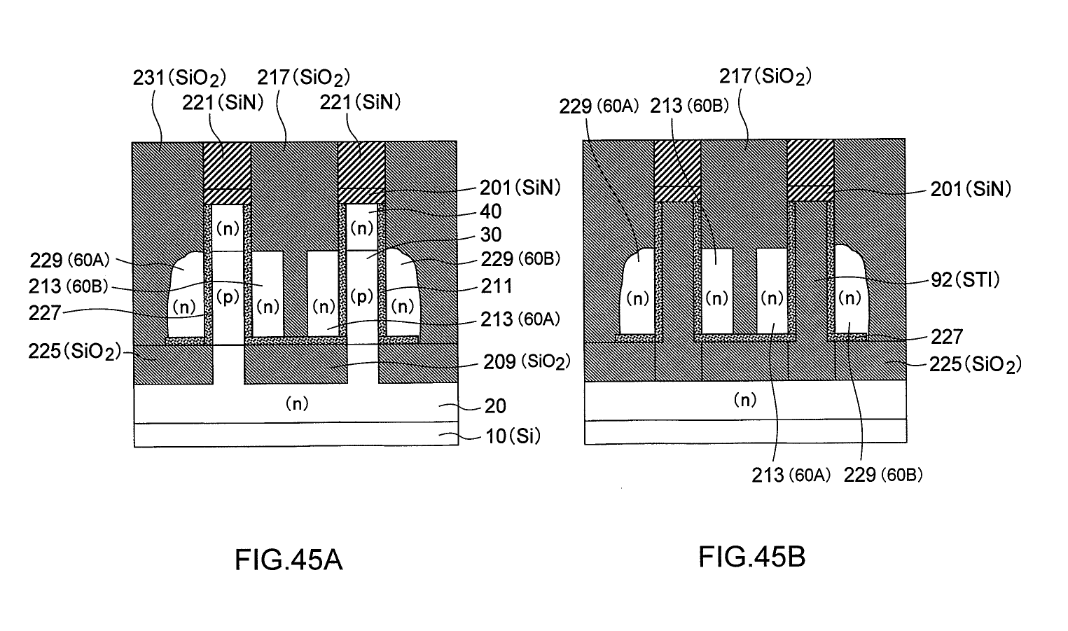

A silicon oxide film 231 is then buried in the trench 223 by a CVD process and its surface is flattened by CMP. With this process, a configuration shown in FIGS. 45A and 45B is obtained.

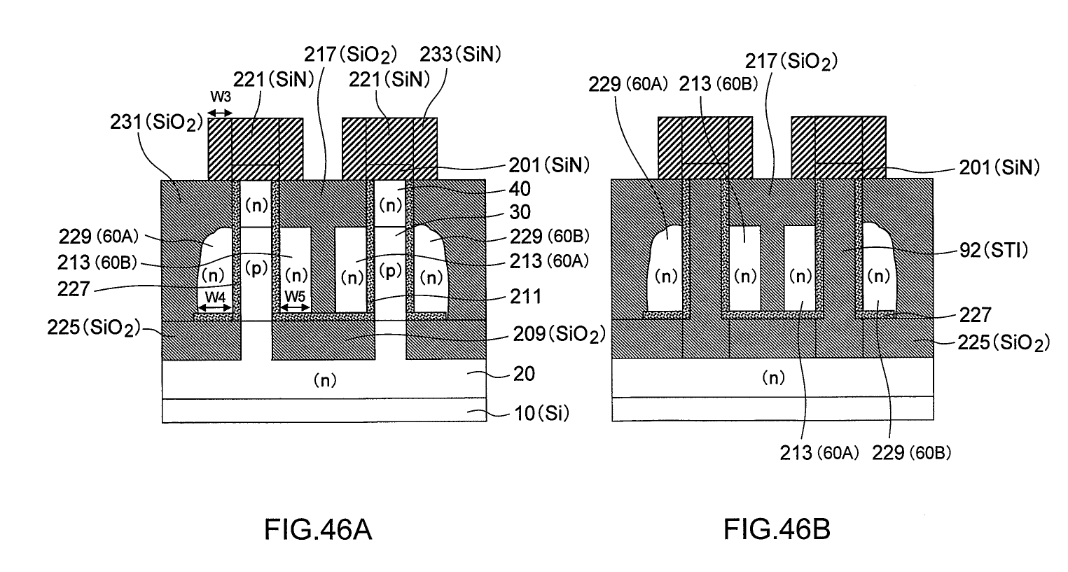

Next, as shown in FIGS. 46A and 46B, the silicon oxide film 231 is etched back to the top surface of the drain layer 40. Subsequently, a silicon nitride film 233 is deposited on the silicon nitride films 221 and 201 and on the silicon oxide film 217. The silicon nitride film 233 is then anisotropically etched by RIE so as to remain as a sidewall on the side surfaces of the silicon nitride films 221 and 201. At this time, the thickness (width) W3 of the silicon nitride film 233 deposited in a transverse direction on the side surfaces of the silicon nitride films 221 and 201 is desirably slightly smaller than the thicknesses (widths) W4 and W5 of the gate electrodes 60A and 60B deposited in the transverse direction on the side surface of the ferroelectric film 227. This is because a part of surfaces of the gate electrodes 60A and 60B is exposed to form silicide on the gate electrodes 60A and 60B in a subsequent step.

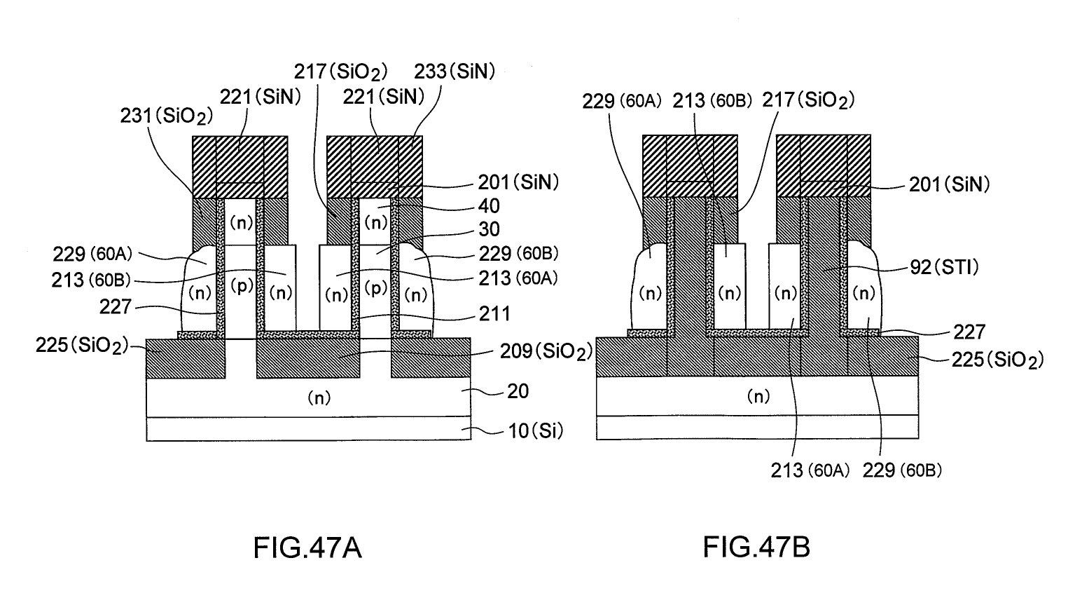

Next, as shown in FIGS. 47A and 47B, the silicon oxide film 231 is anisotropically etched by RIE using the silicon nitride films 221 and 233 as a mask. At this time, because the thickness (width) W3 of the silicon nitride film 233 deposited is slightly smaller than the thicknesses (width) W4 and W5 of the gate electrodes 60A and 60B deposited, only the side surfaces of the gate electrodes 60A and 60B are exposed. The side surface of the drain layer 40 is covered by the ferroelectric films 211 and 227 and the ferroelectric films 211 and 227 are covered and protected by the silicon oxide film 231.

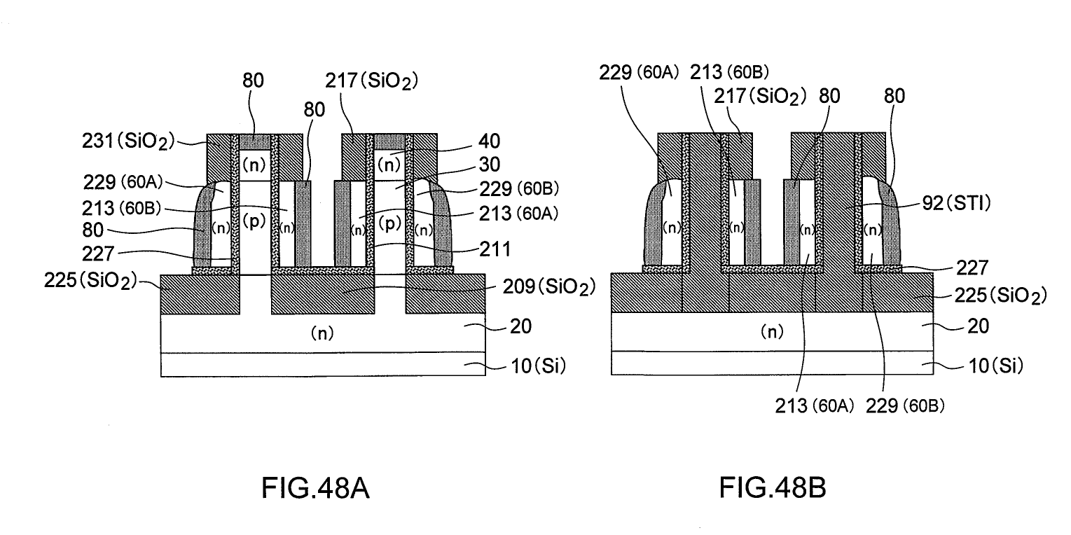

The silicon nitride films 201, 221, and 233 are then removed, so that the drain layer 40 is exposed. A metal film (not shown) is deposited on the gate electrodes 60A and 60B and on the drain layer 40 and thermally treated. The metal film is made of titanium, cobalt, or nickel, for example. In this manner, as shown in FIGS. 48A and 48B, the silicide layer 80 is formed on the gate electrodes 60A and 60B and on the drain layer 40.

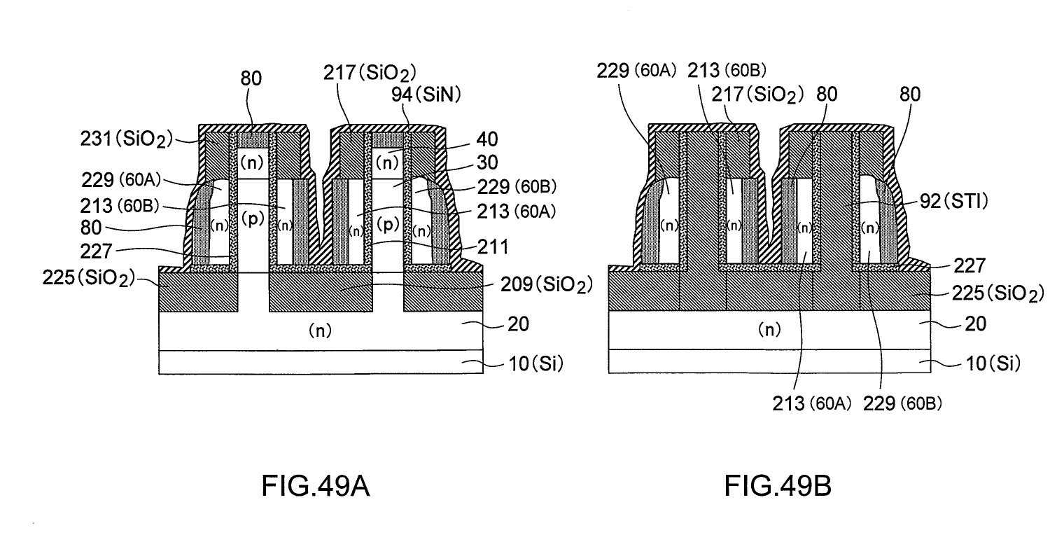

Next, as shown in FIGS. 49A and 49B, the silicon nitride film 94 which becomes a liner film is deposited on the surfaces of the gate electrodes 60A and 60B and the drain layer 40.

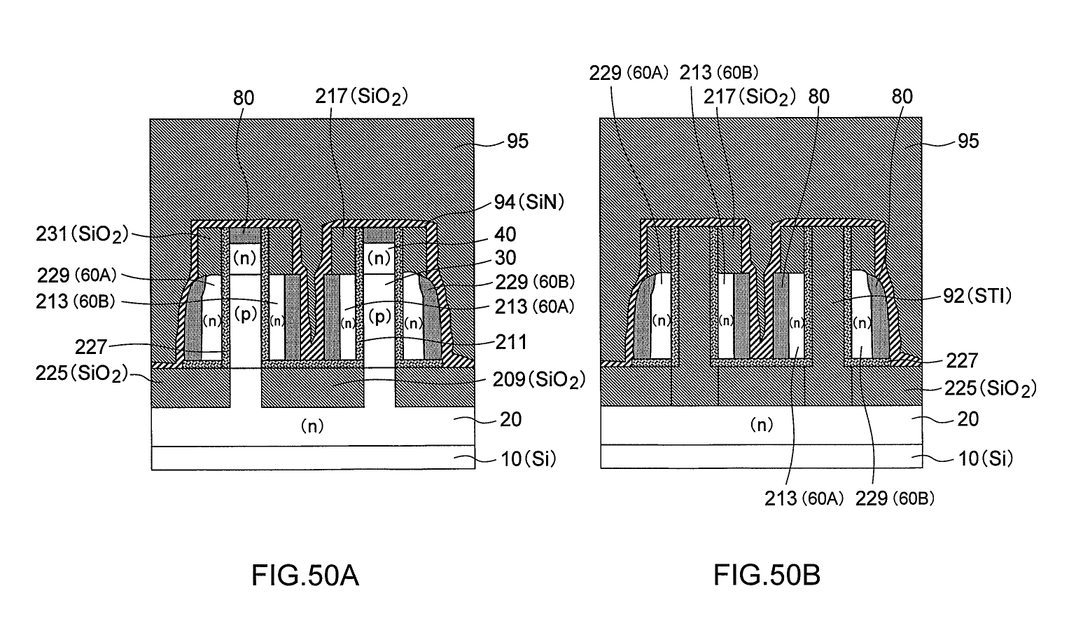

Next, as shown in FIGS. 50A and 50B, a silicon oxide film 95 which becomes an interlayer dielectric film is deposited on the surface of the liner film 94.

Thereafter, the silicon oxide film 95 and the liner film 94 at a part where the bit line BL is to be formed are removed by lithography and RIE. In this manner, a trench reaching the silicide layer 80 on the drain layer 40 is formed at the part where the bit line BL is to be formed. A laminated barrier metal (not shown) consisting of a Ti film and a TiN film is then deposited in the trench at the part where the bit line BL is to be formed and then tungsten is buried in the trench. In this manner, the bit line BL contacting the silicide layer 80 on the drain layer 40 is formed. Thereafter, insulating films and wirings (both not shown) are formed if necessary. With this arrangement, the double gate ferroelectric memory shown in FIGS. 29A and 29B is completed.

The ferroelectric films 227 and 211 function as the first gate dielectric film 50A or the second gate dielectric film 50B and the polysilicon layers 229 and 213 function as the first gate electrode 60A or the second gate electrode 60B. The silicon oxide films 217, 231, and 225 correspond to the silicon oxide films 93, 231, and 91 shown in FIG. 29A or 29B, respectively.

The second embodiment can have a configuration identical to that of the first embodiment, and thus the second embodiment can achieve effects identical to those of the first embodiment.

In the manufacturing method of the second embodiment, at least either of the materials or thicknesses of the first gate dielectric film 50A and the second gate dielectric film 50B included in the same memory cell MC can be different from each other. Further, according to the manufacturing method of the second embodiment, at least either of the materials, thicknesses, or impurity densities of the first gate electrode 60A and the second gate electrode 60B included in the same memory cell MC can be different from each other. As the configuration of the first gate dielectric film 50A is made different from that of the second gate dielectric film 50B or the configuration of the first gate electrode 60A is made different from that of the second gate electrode 60B, the threshold voltage of an FET on the first gate electrode 60A side becomes different from that of an FET on the second gate electrode 60B side in the same memory cell MC. Accordingly, even if voltages of two adjacent word lines WLA and WLB are equal to each other in the read operation, the sense amplifier S/A can distinguish data (0, 1) from data (1, 0) in the selected memory cell MCsel. Therefore, even if the voltages of the two adjacent word lines WLA and WLB are equal to each other, the sense amplifier S/A can read 2-bit data of the selected memory cell MCsel.

### First Modification of Second Embodiment

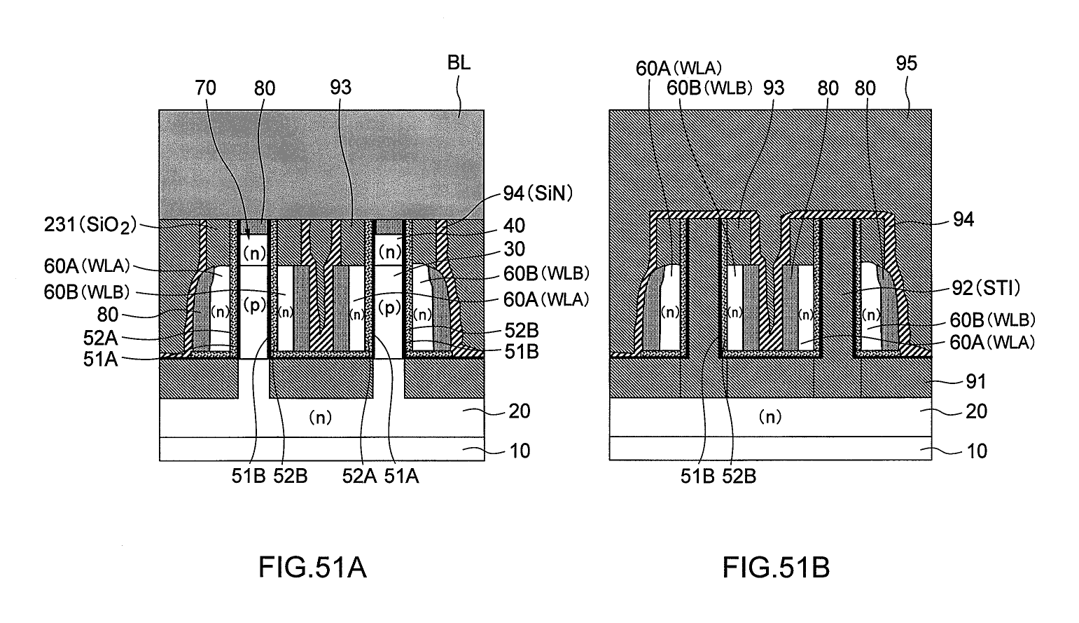

FIGS. 51A and 51B are cross-sectional views of a double gate ferroelectric memory according to a first modification of the second embodiment. This modification is achieved by combining the first modification of the first embodiment with the second embodiment. According to the second embodiment, the gate dielectric films 50A and 50B as ferroelectric films are placed so as to contact directly the side surface of the body region 30. However, when the ferroelectric film is provided directly on the silicon layer 101, a ferroelectric material may diffuse in channels of the body region 30. To prevent such diffusion of the ferroelectric material, as shown in FIGS. 51A and 51B, the first insulating films 51A and 51B made of a paraelectric film (silicon oxide film, HfO₂, Y₂O₃, HfSiON, HfSiO, Ta₂O₅, BaTiO₃, BaZrO₃, ZrO₂, Al₂O₃) are formed on the side surface of the silicon layer 101 and the second insulating films 52A and 52B made of a ferroelectric film with polarization characteristics are formed on the first insulating films 51A and 51B of this modification. The first gate dielectric film 50A includes the first insulating film 51A made of a paraelectric film between the second insulating film 52A made of a ferroelectric film and one side surface of the body region 30. The second gate dielectric film 50B includes the second insulating film 51B made of a paraelectric film between the second insulating film 52B made of a ferroelectric film and the other side surface of the body region 30.

Accordingly, the first insulating films 51A and 51B function as a buffer in process and can prevent the ferroelectric material from diffusing in the body region 30 in a thermal treatment step. The first insulating films 51A and 51B made of a paraelectric body are provided between the body region 30 and the second insulating film 52A made of a ferroelectric film and between the body region 30 and the second insulating film 52B made of a ferroelectric film, respectively. Reduction of carrier mobility in the body region 30 can be also suppressed.

While an N-channel transistor is used for the memory cell MC in the above embodiments, the memory cell MC can be a P-channel transistor. In the case of a P-channel transistor, the sign of voltage of each electrode becomes reversed in its driving method. With this arrangement, even if the memory cell MC is a double gate ferroelectric memory which is a P-channel transistor, effects identical to those of the above embodiments can be achieved.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the invention.

1. A semiconductor memory device comprising:
a semiconductor substrate;
at least one first conductive-type first diffusion layer on a surface of the semiconductor substrate;
a plurality of second conductive-type body regions on the first diffusion layer or the first diffusion layers;
a plurality of first conductive-type second diffusion layers on the body regions;
a plurality of first gate dielectric films comprising ferroelectric films and provided on first side surfaces of the body regions;
a plurality of second gate dielectric films comprising ferroelectric films and provided on second side surfaces of the body regions opposite to the first side surfaces;
a plurality of first gate electrodes each of which is on the first side surface of the body region with the first gate dielectric film interposed therebetween; and
a plurality of second gate electrodes each of which is on the second side surface of the body region with the second gate dielectric film interposed therebetween, wherein
the first and the second diffusion layers, the body region, the first and the second gate dielectric films, and the first and the second gate electrodes constitute a plurality of memory cells, and
each of the memory cells stores a plural pieces of logical data depending on a polarization state of the first gate dielectric film and on a polarization state of the second gate dielectric film.

2. The device of claim 1, wherein
the first gate dielectric film comprises a first insulating film made of a paraelectric film between a ferroelectric film and the first side surface of the body region, and
the second gate dielectric film comprises a second insulating film made of a paraelectric film between a ferroelectric film and the second side surface of the body region.

3. The device of claim 1, wherein the first diffusion layer is common to all of the memory cells.

4. The device of claim 2, wherein the first diffusion layer is common to all of the memory cells.

5. The device of claim 1, wherein
the first gate electrode and the second gate electrode are electrically separated from each other and function as two different word lines,
the second diffusion layer is electrically connected to a bit line crossing the word line, and
each of the body regions is provided for two intersections of two of the word lines and the bit line.

6. The device of claim 2, wherein
the first gate electrode and the second gate electrode are electrically separated from each other and function as two different word lines,
the second diffusion layer is electrically connected to a bit line crossing the word line, and
each of the body regions is provided for two intersections of two of the word lines and the bit line.

7. The device of claim 3, wherein
the first gate electrode and the second gate electrode are electrically separated from each other and function as two different word lines,
the second diffusion layer is electrically connected to a bit line crossing the word line, and
each of the body regions is provided for two intersections of two of the word lines and the bit line.

8. The device of claim 1, wherein each of the body region and the second diffusion layer constitutes a semiconductor pillar.

9. The device of claim 2, wherein each of the body region and the second diffusion layer constitutes a semiconductor pillar.

10. The device of claim 3, wherein each of the body region and the second diffusion layer constitutes a semiconductor pillar.

11. The device of claim 1, wherein
the first diffusion layer, the body region, and the second diffusion layer are arranged in a vertical direction in each of the memory cells, and
at a time of reading data from the memory cell, a current flows within the body region in a direction substantially vertical to a surface of the semiconductor substrate.

12. The device of claim 2, wherein
the first diffusion layer, the body region, and the second diffusion layer are arranged in a vertical direction in each of the memory cells, and
at a time of reading data from the memory cell, a current flows within the body region in a direction substantially vertical to a surface of the semiconductor substrate.

13. The device of claim 3, wherein
the first diffusion layer, the body region, and the second diffusion layer are arranged in a vertical direction in each of the memory cells, and
at a time of reading data from the memory cell, a current flows within the body region in a direction substantially vertical to a surface of the semiconductor substrate.

14. The device of claim 1, wherein material or thickness of the first gate dielectric film is different from that of the second gate dielectric film.

15. The device of claim 2, wherein material or thickness of the first gate dielectric film is different from that of the second gate dielectric film.

16. The device of claim 1, wherein material, thickness, or impurity density of the first gate electrode is different from that of the second gate electrode.

17. The device of claim 14, wherein material, thickness, or impurity density of the first gate electrode is different from that of the second gate electrode.

18. A driving method of a semiconductor memory device comprising a semiconductor substrate, at least one first conductive-type first diffusion layer on a surface of the semiconductor substrate, a plurality of second conductive-type body regions on the first diffusion layer or the first diffusion layers, a plurality of first conductive-type second diffusion layers on the body regions, a plurality of first gate dielectric films comprising ferroelectric films and provided on a first side surface of the body region, a plurality of second gate dielectric films comprising a ferroelectric film and provided on a second side surface of the body region opposite to the first side surface, a plurality of first gate electrodes each of which is on the first side surface of the body region with the first gate dielectric film interposed therebetween, and a plurality of second gate electrodes each of which is on the second side surface of the body region with the second gate dielectric film interposed therebetween, wherein the first and the second diffusion layers, the body region, the first and the second gate dielectric films, and the first and the second gate electrodes constitute a plurality of memory cells,
the driving method comprising, at a time of reading data from a memory cell selected among the memory cells, applying different voltages to the first gate electrode of the selected memory cell and to the second gate electrode thereof.
